(19) United States
(12) Patent Application Publication
(10) Pub. No.: US 2016/0276067 A1
(43) Pub. Date: Sep. 22, 2016

(54) METHOD FOR PRODUCING SUBSTRATES FOR SUPERCONDUCTING LAYERS

(71) Applicant: DANMARKS TEKNISKE UNIVERSITET, Kgs. Lyngby (DK)

(72) Inventor: Anders Christian Wulff, Smørum (DK)

(21) Appl. No.: 15/034,146

(22) PCT Filed: Nov. 20, 2014
(86) PCT No.: PCT/DK2014/050395

§ 371 Date: May 3, 2016

(30) Foreign Application Priority Data
Nov. 20, 2013 (EP) 13193734.4

(51) Int. Cl. H01B 12/10; H01L 39/04; H01L 39/12; H01B 12/06; C25D 3/12; C25D 5/14; C25D 5/40; C25D 5/48; C25D 5/02; C25D 5/12; C25D 3/38; C25F 3/02; H01B 13/00; H01B 13/008; H01L 39/24

(52) U.S. Cl. CPC H01B 12/10; H01L 39/248; H01L 39/04; H01L 39/126; H01B 12/06; C25D 3/12; C25D 5/14; C25D 5/40; C25D 5/48; C25D 5/022; C25D 5/12; C25D 3/38; C25F 3/02; H01B 13/0009; H01B 13/008

(57) ABSTRACT

There is provided a method for producing a substrate suitable for supporting an elongated superconducting element, wherein one or more elongated strips of masking material are placed on a solid element (202) so as to form one or more exposed elongated areas being delimited on one or two sides by elongated strip of masking material, and placing filling material on the solid element so that each exposed elongated area within the one or more exposed elongated areas is covered by a portion of filling material (318a-c) where each portion of filling material also covers at least a portion of the adjacent elongated strip of masking material and subsequently removing the one or more elongated strips of masking material so as to form one or more corresponding undercut volumes, where each undercut volume within the one or more undercut volumes is formed along a portion of filling material and between the portion of filling material and the solid element. The method may further comprise placing buffer material (640) and or superconducting material (642, 644, 646)) on the substrate, so as to provide a superconducting structure (601) with reduced AC losses.

### FIELD OF THE INVENTION

The present invention relates to a method for producing substrates, and in particular relates to substrates suitable for supporting an elongated superconducting element, and a corresponding method for producing and using such substrates.

### BACKGROUND OF THE INVENTION

Superconducting structures may be seen as advantageous since they enable conducting current without resistive losses. Superconducting structures, such as superconducting tapes are thus being used for a number of applications, such as generators and transformers. However, although they possess excellent properties when carrying direct current, they may exhibit high losses when used in alternating current (AC) applications.

Means of reducing AC losses that are currently available may not in a straightforward manner be adapted to processing long lengths of superconducting tape.

In the application U.S. Pat. No. 7,593,758 B2 there is presented a tape which has a high temperature superconductor layer that is segmented. Disruptive strips, formed in one of the tape substrate, a buffer layer, and the superconducting layer create parallel discontinuities in the superconducting layer that separate the current-carrying elements of the superconducting layer into strips or filament-like structures. Segmentation of the current carrying elements has the effect of reducing AC losses. Methods of making such a superconducting tape and reducing AC losses in such tapes are also disclosed.

In the application U.S. Pat. No. 4,101,731 there is presented a composite multifilament superconducting structure is provided, which includes an elongated substrate-carrying, longitudinally-directed, sputtered discrete filament of an A-15 type intermetallic superconductor. In a preferable procedure, a plurality of spaced, generally longitudinal grooves are formed on the surface of an elongated filamentary substrate, preferably a metal wire. The walls of the grooves on the substrate surface are shaped to undercut the curvilinear surface of the substrate located between two adjacent grooves so that at least some of the wall portions of the grooves are geometrically shadowed during the subsequent sputtering step in which a superconductor is sputtered onto the substrate. In particular, a film of a suitable superconducting intermetallic compound having A-15 crystalline structure, such as Nb₃Ge, is thereupon sputtered onto the grooved substrate and deposits at the bottom of the grooves and at the surface portions of the substrate between grooves. The shadowed wall portions remain substantially deposit-free so that the resultant spaced deposits extend as distinct lines or bands along the substrate to thereby constitute the superconductive filaments. A plurality of such substrates may, if desired, be consolidated into a further composite structure, by bundling the substrates and passing same through a molten metal. The resultant structure may then be sized to yield as a foral product a composite of the substrates bearing the superconducting filaments in a surrounding matrix of the metal.

### SUMMARY OF THE INVENTION

It may be seen as a problem with the prior art methods that they are not adaptable to continuous processing of long lengths of such tape, effective, cheap, enabling low material consumption and/or provides a good substrate for a superconducting tape. It would be advantageous to have a method for making a substrate for a superconducting tape having reduced AC losses, wherein the method is adaptable to continuous processing of long lengths of such tape and which method would be effective, cheap and/or would be a method which provided an improved substrate for a superconducting tape compared to the prior art.

It may be seen as an object of the present invention to provide a method of making a substrate for a superconducting tape having reduced AC losses which is adaptable to continuous processing of long lengths of such tape and which method is effective, cheap and/or which provides an improved substrate for a superconducting tape that solves the above mentioned problems of the prior art.

It is a further object of the present invention to provide an alternative to the prior art.

Thus, the above described object and several other objects may be obtained in a first aspect of the invention by providing a method for producing a substrate suitable for supporting an elongated superconducting element, such as a superconducting tape having reduced AC losses, the method comprising, such as comprising the steps of:
Providing a solid element, such as a solid nickel based alloy, such as a solid nickel or copper or chrome based alloy,
Placing one or more elongated strips of masking material, such as Kapton® tape or scotch tape or imprint resist or photoresist, on the solid element, where the one or more elongated strips of masking material are arranged so as to form one or more exposed elongated areas, where each exposed elongated area within the one or more exposed elongated areas is delimited on one or two sides by at least one elongated strip of masking material, such as one elongated strip of masking material, such as two adjacent elongated strips of masking material, within the one more elongated strips of masking material,
Placing, such as placing via electrodeposition or via electroplating or via IBAD or via dip-coating, such as via dip coating in combination with selective surface treatment or via ink-jet printing or via electroforming, filling material, such as nickel, such as placing nickel via electrodeposition, on the solid element so that each exposed elongated area within the one or more exposed elongated areas is covered by a portion of filling material, such as covered by a coherent portion of filling material, where each portion of filling material also covers at least a portion of the adjacent elongated strip of masking material, such as one or both of the adjacent elongated strips of masking material,
Removing, such as removing by etching or electroetching or dissolving, the one or more elongated strips of masking material so as to form one or more corresponding undercut volumes, where each undercut volume within the one or more undercut volumes is formed along a portion of filling material and between the portion of filling material and the solid element.

The invention is particularly, but not exclusively, advantageous for obtaining a method for producing a substrate suitable for supporting an elongated superconducting element, which method enables employing a large number of solid element materials, i.e., the method enables choosing between many different materials for the lower layer, since the material properties of the lower layer are not decisive in terms of enabling achieving the undercuts. Another advantage may be that the method enables choosing between many different materials for the filling material. For example, the filling material may be a material suitable for functioning as buffer layer, such as a dip-coated buffer layer, which may be advantageous in that the portions of the filling material may immediately be ready for deposition of a superconducting layer after removal of the one or more elongated strips of masking material (or maybe even before removal of the masking material). Furthermore, the substrate generated by the method enables efficiently separating closely spaced lines of superconducting material.

Another possible advantage of the present invention may be that it enables are large degree of control over the geometry of the substrate, such as the geometry of the portion(s) of the filling material adjacent to the undercut volumes. For example, the undercut volumes may be round, rectangular, triangular or other shapes designed by the user and have different proportions and aspect rations depending on the desires of the designer.

The gist of the invention may be seen as providing a method which in a few relatively simple steps enables providing a substrate which may be turned into a superconducting structure, such as a superconducting tape, having reduced AC losses. The basic insight underlying the invention may be described as the insight that undercut volumes (such as undercut volumes in a structure, such as between the solid element and the one or more portions of filling material) may be useful for separating layers of material which are positioned on top of the structure which comprises the undercut volumes, and that the undercut volumes may be formed by removal of the elongated strips of masking material so as to leave behind the filling material which is shaped, such as shaped by the masking material, so that undercuts may be formed between the one or more portions of filling material and the solid element. Thus, relatively simple steps, for example placement of masking strips, placement of filling material (at least partially on top of the masking material thereby enabling forming the undercuts), may be employed in combination so that a solution to the technical problem of ‘providing a method which in a few relatively simple steps enables providing a substrate which may be turned into a superconducting structure, such as a superconducting structure with a striated superconductor’ may be achieved. The superconducting element or superconducting structure may be realized by, e.g., depositing a layer of superconducting material on top of the solid element wherein undercuts have been formed along portions of filling material. The undercuts serve to physically separate the superconducting material on each portion of filling material, and superconducting material next to portions of filling material, such as between adjacent portions of filling material, thereby effectively forming a striated superconducting layer. The undercuts may furthermore serve to physically separate both the superconducting material and additionally deposited layers, such as shunt and/or capping layers, on each portion of filling material, and superconducting material next to portions of filling material, such as between adjacent portions of filling material, thereby effectively forming a striated superconducting layer.

The method is furthermore applicable, such as well-suited, for large-scale manufacturing, since it is a relatively simple procedure to, e.g., place elongated strips of masking material on a solid element, place filling material on the exposed elongated areas next to the strips of masking material and partially on the masking material, and remove the masking material, even on a large scale.

Thus, large scale manufacturing is possible with embodiments of the invention, and furthermore, this is possible while minimizing material costs.

Embodiments of the invention may furthermore be seen as cost effective, which is in contrast to, e.g., laser stripping which is not considered cost effective. It may also be seen as an advantage over laser stripping that embodiments of the present invention might not suffer from redeposition of stripped material. Embodiments of the invention may furthermore be seen as effective in terms of enabling providing substrates for superconducting structures facilitating relatively large critical currents because there will be little or no damage zones and/or because an effective width of the superconductor may be enlarged corresponding to a width of the solid element (since superconducting layers deposited on and between one or more portions of filling material may partially overlap each other). Furthermore, alternative techniques may generally yield a damage zone, i.e. a portion of superconducting material which is no longer functional, after striating the superconducting element, which is in turn reducing the critical current of the striated superconductor.

It may be understood that the steps are not necessarily arranged in the order in which they are to be carried out. In some embodiments, however, the steps are arranged in the order in which they are to be carried out.

By ‘a substrate suitable for supporting an elongated superconducting element’ is understood a solid element upon which a superconducting material may be placed, such as deposited, so that the substrate and the superconducting element may together form an elongated superconducting element. By elongated superconducting element is understood a superconducting element which is able to conduct current a distance in a direction, where the distance is longer, such as significantly longer, such as 2, 5, 10, 100, 1.000, 10.000 or 100.000 times longer than the width of the conductor in a direction orthogonal to the direction in which current is conducted. The length of the substrate may be at least 1 m, such as at least 10 m, such as at least 100 m, such as at least 1 km, such as at least 10 km, such as at least 100 km, such as at least 100 km. It may be understood, that the lengths of one or more or all of the elements optionally placed on the substrate, such as elongated strips of masking material, filling material, buffer, superconducting material, shunt layer may have a length being similar to or identical to the length of the substrate.

It may be understood that the method may be carried out on a side of a solid element, such as on a single side or multiple sides of the solid element (such as on one or both sides of a solid element being a tape, such as on one or two or three sides of a solid element having a triangular shape, such as on 1-n sides of a solid element having a n-polygonal shape). Carrying out the method on multiple sides of a solid element may be beneficial for enabling providing a superconductor capable of carrying more current.

In a particular embodiment, the substrate is a ‘tape’, i.e., an element which has thickness (length along a first dimension) which is significantly smaller, such as 10, 100 or 1000 times smaller, than its width (length along a second dimension) and where the width is significantly smaller, such as 10, 100, or 1.000 times smaller, than its length (length along a third dimension).

By ‘solid element’ may be understood an element comprising a solid phase, such as consisting of a solid phase. The solid element may be a planar solid element, such as a tape. The solid element may also have other shapes, where shapes are understood as the geometrical form as seen in a cross-section in a plane being orthogonal to a length axis (such as corresponding to an axis parallel with a direction in which current is to be carried), such as an arbitrary shape, such as any one of a tape-shape, a rectangular shape (such as a quadratic shape), a triangular shape, an ellipsoidal shape (such as a circular shape). The solid element may comprise any material selected from the group comprising: a nickel based alloy, a copper based alloy, a chrome based alloy, iron, aluminum, silicon, titanium, tungsten (also known as wolfram (W)), silver, hastelloy, and stainless steel.

By ‘hastelloy’ is understood an alloy wherein the predominant alloying ingredient is nickel and wherein other alloying ingredients are added, such as the alloy comprising varying percentages of one or more of, such as all of, the elements: molybdenum, chromium, cobalt, iron, copper, manganese, titanium, zirconium, aluminium, carbon, and tungsten. In a particular embodiment, hastelloy is an alloy which comprises the elements Ni, Cr, Fe, Mo, Co, W, C. In a more particular embodiment, the alloy also comprises Ni, Cr, Fe, Mo, Co, W, C and one or more of the elements Mn, Si, Cu, Ti, Zr, Al and B. In a more particular embodiment, the alloy is understood to comprise approximately 47 wt % Ni, 22 wt % Cr, 18 wt % Fe, 9 wt % Mo, 1.5 wt % Co, 0.6 wt % W, 0.10 wt % C, less than 1 wt % Mn, less than 1 wt % Si and less than 0.008 wt % B. Hastelloy may be referred to as “superalloy” or a “high-performance alloy” within the art.

‘Stainless steel’ is generally known in the art. In particular embodiments, there is provided stainless steel with nickel and/or chromium, such as to provide a stainless steel which is corrosion and/or oxidation resistant, mechanically stable and non-magnetic at the operation temperature of the superconducting layer.

By ‘elongated’ may be understood as referring to something having a larger dimension in a first direction (such as the direction referred to as the length direction), such as significantly longer, such as 2, 5, 10, 100, 1.000, 10.000 or 100.000 times longer than the dimension in one or both of the other two directions (such as the directions referred to as width and height) orthogonal to the first direction. The length may be at least 1 m, such as at least 10 m, such as at least 100 m, such as at least 1 km, such as at least 10 km, such as at least 100 km, such as at least 100 km. The length may in particular embodiments be 1 m, such as 100 m, such as 1 km, such as 20 km, such as 100 km, such as above 100 km, such as within 1 m-30 km, such as within 1 km-30 km.

By ‘one or more elongated strips of masking material’ may be understood an elongated element which may serve the purpose of masking the solid element. ‘Masking’ is understood as is common in the art. The masking material may comprise any material selected from the group comprising: Kapton® tape, scotch tape, wax, laquer, imprint resist, polymer and photoresist. An advantage of using Kapton® tape or scotch tape may be that it offers a relatively simple process, e.g., as an alternative to, e.g., lithographic techniques which may not applicable for large scale manufacturing as a photo-resist has to be coated, exposed to e.g. UV-light and following developed to produce masking strips.

Throughout this application, it is understood that ‘Kapton® film’ refers to the well-known product from DuPont™ which is a film of poly(4,4′-oxydiphenylene-pyromellitimide). Kapton® film and Kapton® tape are used interchangeably.

By ‘placing one or more elongated strips of masking material’ may be understood any process resulting in a masking material being placed onto the solid element, so as to mask the solid element and thereby forming one or more exposed elongated areas′. The process of ‘placing one or more elongated strips of masking material’ may comprise a process chosen from the group comprising: ink-jet printing (such as ink-jet printing selectively in areas which are not supposed to become exposed elongated areas). Alternatively, the step of placing one or more elongated strips of masking material on the solid element, may be embodied by placing a film, such as a Kapton® film, a wax or a lacquer on top of the solid element. In different embodiments, the strips (i.e., strips of masking material) may be formed before and/or after the film or layer, such as a coherent film or layer, is placed on the solid element. In other words, the elongated strips may be placed on the solid element as elongated strips, but it may also be conceivable, that a coherent film or layer is placed on the solid element, and where portions of the film or layer are subsequently removed so as to leave behind the elongated strips of masking material. For example, a striated layer of masking material comprising a plurality of elongated strips of masking material, may be provided, e.g., by means of a plurality of strips of Kapton® film which are placed onto the solid element, such that the areas between the strips of Kapton® film form exposed elongated areas. In another possible embodiment ‘placing one or more elongated strips of masking material’ may be carried out using solution planarization deposition.

It may be understood that masking material, such as a coherent masking material, such as a completely covering masking material, may be placed on parts of the solid element, which parts are not covered by elongated strips of masking material or correspond to exposed elongated areas. For example, in case the solid element is a relatively flat element, such as a tape, a coherent masking material may be placed on a lower (back-)side of the solid element, so as to protect this side and/or to avoid that filling material is deposited there.

In another example, the ‘placing one or more elongated strips of masking material’ comprises placing a coherent masking material on the solid element, and removing masking materials above the areas corresponding to the exposed elongated areas by a removal process comprising, e.g., a process chosen from the group comprising: a cutting process, a scratching process, a rolling process, a grinding process and a polishing process. By a ‘scratching process’ is understood that a portion of the upper layer and possibly a portion of the lower layer is scratched off, such as scraped off. By ‘a grinding process’ is understood that a portion of the masking material is removed by a grinding process or polishing, such as repeatedly scraping off minor portions of the material to be removed. A ‘polishing process’ is understood to be similar to a ‘grinding process’ in the present context. By a ‘cutting process’ is understood a process wherein masking material is displaced, such as displaced rather than removed. This may be achieved using a relatively sharp tool, such as a cutting wheel. By a ‘rolling process’ is understood a process where e.g. masking material is displaced, such as removed by displacement, such as wax being displaced.

By ‘the one or more elongated strips of masking material are arranged so as to form one or more exposed elongated areas’ may be understood that elongated areas on the solid element which are not covered by the masking material, may be referred to as elongated exposed areas. These areas may be exposed to processes which the areas covered by the masking material may not be exposed to. It may be understood that the exposed areas denote fixed areas on the solid element, i.e., the ‘exposed areas’ may, e.g., in subsequent steps not be exposed, e.g., after placement of filling material and removal of the masking material. In other words, the reference to ‘exposed areas’ (which are used interchangeably with exposed elongated areas’) may be understood to refer substantially to the negative of the areas covered by masking material, even after removal of the masking material.

By ‘exposed elongated areas’ may be understood ‘exposed areas of the solid element’ which may be understood as areas of the solid element which are not covered by masking material, such as areas between adjacent elongated strips of masking material. However, an ‘exposed elongated area’ may also be delimited on only one side by an elongated strip of masking material, and on the other side by another structural feature, such as an edge of the solid element. It may be understood that when referring to two sides of the exposed elongated area, these two sides, are the two sides in the plane of the surface of the exposed elongated area which are on either side of the exposed elongated area in a direction being orthogonal to a length direction of the exposed elongated area.

By ‘each exposed elongated area within the one or more exposed elongated areas is delimited on one or two sides by at least one elongated strip of masking material’ may be understood that the elongated exposed areas are delimited on at least one side by the masking material, but may be delimited on both sides by masking material, such as two adjacent elongated strips of masking material. Alternatively, the elongated exposed areas are delimited on one side by the masking material and on the other side by another structural element, which may for example be an edge of the solid element.

By ‘placing filling material’ may be understood any process resulting in a solid material being placed onto the exposed elongated areas, so as to at least partially fill a volume above the exposed elongated areas which volume extends at least partially into a volume above the adjacent elongated strip(s) of masking material. The process of ‘placing filling material’ may comprise a process chosen from the group comprising: electrodeposition (such as electrodeposition where the solid element is an electrically conducting material and the masking material is a less conducting, such as electrically isolating material), electroplating, electroforming, Pulsed Laser Deposition, Alternating Beam Assisted Deposition (ABAD), Ion Beam Assisted Deposition (IBAD) (such as IBAD leading to material only being deposited primarily, such as only on the elongated exposed areas), dip-coating (such as dip-coating in combination with selective surface treatment, such as selective surface treatment leading to the surface properties of the exposed elongated areas compared to the surface properties of the masking material leading to the exposed elongated areas being more susceptible to deposition compared to the masking material), and ink-jet printing (such as ink-jet printing selectively in the exposed elongated areas). It may be understood that the filling material may be chosed from the group comprising: nickel, chromium, tungsten, vanadium, aluminum, aluminum oxide (Al₂O₃), iron, copper, tin, silicon (Si), gadolinium, cobalt, molybdenum, GdZrO, CeO₂, ZrO, yttrium oxide (Y₂O₃), Yttrium Stabilished Zirconium and zirconium (Zr). In an embodiment, the placing of filling material comprises placing nickel via electrodeposition, such as plating, such as electroplating, on the solid element. It may in general be noted, that it may be beneficial that the filling material has a relatively smooth surface, since this may be beneficial for subsequent deposition and utilization of superconducting material. In an embodiment, filling material, such as nickel or chrome, is deposited so as to obtain a smooth surface, such as by controlling the current density (and thus the deposition rate) and/or by filtering of the electroplating solution. It may also be understood that filling material may be deposited by controlling current density and/or voltage and/or controlling the temperature of e.g. the plating solution. Various deposition parameters affecting the surface roughness are described in each of the following references: A) Metal Finishing, 79th Surface Finishing Guidebook, Fall 2011 VOLUME 109 NUMBER 11A, ISSN 0026-0576 and B) Rustfrit stål og corrosion, Claus Qvist Jessen, 1. udgave, 1. oplag 2011, ISBN 978-87-92765-00-0, Forlaget Møller & Nielsen, which are each hereby incorporated by reference in entirety. In another possible embodiment ‘placing filling material’ may be carried out using solution planarization deposition.

It may be beneficial for the subsequent formation of a superconducting layer that the surface roughness of the substrate is relatively low. In order to decrease the surface roughness at the positions where there is filling material, such as the surfaces of the portions of filling material, and the substrate in general, an electropolishing step and/or a buffer layer deposition step can be conducted in order to decrease the surface roughness compared to the roughness of the filling material immediately after electrodeposition, such as electroplating. In one embodiment, the method comprises an electropolishing step, such as an electropolishing step which is carried out while the elongated strips of masking material, such as the Kapton® tape, is still present (i.e., the elongated strips of masking material are not removed from the solid element until the electropolishing step has been carried out), so as to decrease the surface roughness, so as to decrease the surface roughness in order to facilitate improved properties of the substrate in terms of enabling a higher quality of a subsequently deposited superconducting layer.

Generally, for any embodiment of the present invention, the surface (RMS) roughness of the solid element and/or the portions of filling material, may be below 100 nm, such as below 50 nm, such as below 25 nm, such as below 20 nm, such as below 15 nm, such as below 10 nm, such as below 5 nm, such as below 1 nm. An advantage of this may be, that it facilitates having improved properties of a superconducting material which is subsequently placed, such as deposited, on the solid element and/or the portions of filling material.

By ‘so that each exposed elongated area within the one or more exposed elongated areas is covered by a portion of filling material’ may be understood that each exposed area is covered by a portion of filling material, such as completely covered by a portion of filling material, such as completely covered by a coherent portion of filling material. By ‘a coherent portion of filling material’ may be understood that the portion of filling material forms one coherent piece of solid material.

By ‘where each portion of filling material also covers at least a portion of the adjacent elongated strip of masking material’ may be understood that the portion of filling material which covers an exposed elongated area, also covers at least a portion of the adjacent elongated strip of masking material, such as one or both of the adjacent elongated strips of masking material, so that the portion of filling material covers both the exposed area and a portion of masking material. In other words, at least a portion of the masking material is below a portion of filling material.

In an embodiment, the portion of filling material covers only a portion (but not all) of the elongated strip of masking material, such as the portion of filling material covers only a fraction of the masking material, such as covers the edge of masking material (between the masking material and the exposed area), but not all of the masking material in a direction away from the exposed elongated area (as illustrated in the exemplary embodiment shown in FIG. 4). An advantage of this may be, that the masking material is thus relatively easily accessible by, e.g., an etchant or a solvent. Another advantage may be that the masking material may relatively easily be removed, since it is not completely covered by filling material.

By ‘Removing the one or more elongated strips of masking material’ may be understood that the masking material is partially or completely removed from the structure comprising the solid element and filling material. The removal may be carried out by any process selected from the group comprising: etching, dissolving, peeling and evaporation, or combinations thereof. The removal may be carried out by a process wherein the one or more elongated strips of masking material are attached to the solid element via an adhesive, and wherein the step of removing the one or more elongated strips of masking material comprises dissolving the adhesive, such as a protective tape glue, and peeling of the one or more elongated strips of masking material. For example, in case the masking material is Kapton® tape, then the glue on the Kapton® tape may be dissolved by, e.g., ethanol and/or acetone and thereby enabling relatively easy removal of the Kapton® tape by peeling of the Kapton® tape.

By ‘etching (the masking material)’ may be understood that the elongated strips of masking material are etched with an etchant. The etchant may in particular embodiments be in any one of the following states of matter: plasma, liquid and gas. In a particular embodiment Reactive Ion Etching (RIE) is employed.

By ‘form one or more corresponding undercut volumes’ may be understood a process wherein the removal of masking material may lead to the forming of undercut volumes. By ‘corresponding undercut volumes’ may be understood that an undercut volume corresponds to a volume which previously (before removal of masking material) corresponded to a volume occupied by masking material. It may be understood that one strip of masking material may correspond to one or two undercut volumes.

By ‘each undercut volume within the one or more undercut volumes is formed along a portion of filling material and between the portion of filling material and the solid element’ may be understood that the undercut volumes are formed next to a portion of filling material, such as below a sub-portion of filling material which sub-portion of filling material is next to an edge of a portion of filling material, and extends in the same direction as the portion of filling material.

In terms of directions, it is understood when referring to ‘up’ that an up-down axis is defined as being in a direction orthogonal to the surface of the solid element, such as the surface of the solid element upon which the masking material and/or the filling material may be placed, and that ‘up’ is in the direction from the surface of the solid element and away from the solid element, and vice versa for the direction ‘down’, i.e., ‘down’ is the direction from the surface of the solid element and into the solid element. It is understood that the up-down axis is parallel to a y-axis as indicated in the figures, and that ‘up’ is in the positive y-direction. This definition of direction also applies when using the terms ‘above’ and ‘below’ which are given their general meaning. It is noted that the surface of the solid element may not necessarily be planar, in which case the up-down axis remains orthogonal to the surface, and where it is understood that an up-down axis corresponding to one position on the surface need not necessarily be parallel with an up-down axis corresponding to another position on the surface.

By ‘undercut volume’ is understood a volume where no solid material is present, which volume may be below a remaining portion of filling material. Thus an undercut volume may be above the surface of the solid element while still shadowed by an overhanging portion of filling material. Thus, when a material is deposited on the sandwich comprising the solid element and the portion(s) of filling material, (or the portion(s) of filling material after removal of the elongated strips of masking material), using a line-of-sight process for deposition of material in a direction following the up-down-axis from a position above the sandwich comprising the solid element and the portion(s) of filling material (such as the up-down axis being orthogonal to the surface of the solid element at the position of the undercut volume), and undercut volume(s) are present, then the material is not deposited on the portion(s) of the filling material and solid element which borders the undercut volumes, such as which is respectively directly above and below the undercut volume(s).

The invention may in particular embodiments encompass having one or more intermediate layers of material inserted between a bulk portion of the solid element and the elongated strips of masking material, such as having one or more intermediate layers separating the a bulk portion of the solid element and elongated strips of masking material, such as the one or more intermediate layer functioning as a barrier for any one of heat, current and diffusion of atoms, ions and/or molecules between the bulk portion of the solid element and the elongated strips of masking material. In that case, it may be understood that the solid element includes the bulk portion of the solid element, and the intermediate layer, such that an element placed on the intermediate layer is understood to be placed on the solid element. An advantage of having one or more intermediate layers may be that it improves the mechanical properties, such as making the layered solid element stronger or more rigid.

It may be understood, that there may be one or more elongated strips of masking material, such as 1, 2, 3, 4, 5, 6, 7, 8, 9, 10, 50, 100 or 1000 elongated strips of masking material. It may be understood, that there may be one or more exposed elongated areas, such as 1, 2, 3, 4, 5, 6, 7, 8, 9, 10, 50, 100 or 1000 exposed elongated areas. It may be understood, that an elongated strip of masking material may border 1 or 2 exposed elongated areas. It may be understood that an exposed elongated area may border 1 or 2 elongated strips of masking material. Thus, it is conceivable to have embodiments with 1 elongated strip of masking material and 1 exposed elongated area, 2 elongated strips of masking material and 1 exposed elongated area, 2 elongated strips of masking material and 2 exposed elongated areas, 2 elongated strip of masking material and 3 exposed elongated areas, 1 elongated strip of masking material and 2 exposed elongated areas, and so forth. For example, for a 4 mm wide solid element, it may be possible to have from one side to the other: 1 mm masking material, 1 mm exposed area (bordered on both sides by masking material), 1 mm masking material, 1 mm exposed area (bordered by masking material on one side and the edge of the solid element on the other.

In an embodiment, there is provided a method for producing a substrate suitable for supporting an elongated superconducting element, wherein the step of
Placing one or more elongated strips of masking material, such as Kapton® tape or scotch tape or imprint resist or photoresist, on the solid element, where the one or more elongated strips of masking material are arranged so as to form one or more exposed elongated areas, where each exposed elongated area within the one or more exposed elongated areas is delimited on one or two sides by at least one elongated strip of masking material, such as one elongated strip of masking material, such as two adjacent elongated strips of masking material, within the one more elongated strip of masking material,
comprises
Placing a plurality of elongated strips of masking material, such as Kapton® tape or scotch tape or imprint resist or photoresist, on the solid element, where adjacent elongated strips of masking material within the plurality of elongated strips of masking material are arranged so as to form one or more exposed elongated areas, where each exposed elongated area within the one or more exposed elongated areas is formed adjacent to at least one elongated strip of masking material.

According to this embodiment, there is provided a plurality of elongated strips of masking material, such as 2, 3, 4, 5, 6, 7, 8, 9, 10, 50, 100 or 1000 elongated strips of masking material, and at least one exposed area, such as 1, 2, 3, 4, 5, 6, 7, 8, 9, 10, 50, 100 or 1000 exposed elongated areas.

In an embodiment, there is provided a method for producing a substrate suitable for supporting an elongated superconducting element, wherein the step of
Placing one or more elongated strips of masking material, such as Kapton® tape or scotch tape, imprint resist or photoresist, on the solid element, where the one or more elongated strips of masking material are arranged so as to form one or more exposed elongated areas, where each exposed elongated area within the one or more exposed elongated areas is delimited on one or two sides by at least one elongated strip of masking material, such as one elongated strip of masking material, such as two adjacent elongated strips of masking material, within the one more elongated strip of masking material,
comprises
Placing one or more elongated strips of masking material, such as Kapton® tape or scotch tape or imprint resist or photoresist, on the solid element, where the one or more elongated strips of masking material are arranged so as to form a plurality of exposed elongated areas, where each exposed elongated area within the one or more exposed elongated areas is formed adjacent to at least one elongated strip of masking material.

According to this embodiment, there is provided at least one elongated strip of masking material, such as 1, 2, 3, 4, 5, 6, 7, 8, 9, 10, 50, 100 or 1000 elongated strips of masking material, and a plurality of exposed elongated areas, such as 2, 3, 4, 5, 6, 7, 8, 9, 10, 50, 100 or 1000 exposed elongated areas.

In an embodiment, there is provided a method for producing a substrate suitable for supporting an elongated superconducting element, wherein the step of
Placing one or more elongated strips of masking material, such as Kapton® tape or scotch tape or imprint resist or photoresist, on the solid element, where the one or more elongated strips of masking material are arranged so as to form one or more exposed elongated areas, where each exposed elongated area within the one or more exposed elongated areas is delimited on one or two sides by at least one elongated strip of masking material, such as one elongated strip of masking material, such as two adjacent elongated strips of masking material, within the one more elongated strip of masking material,
comprises
Placing a plurality of elongated strips of masking material, such as Kapton® tape or scotch tape or imprint resist or photoresist, on the solid element, where adjacent elongated strips of masking material within the plurality of elongated strips of masking material are arranged so as to form a plurality of exposed elongated areas, where each exposed elongated area within the one or more exposed elongated areas is formed adjacent to at least one elongated strip of masking material, and wherein one or more exposed elongated areas within the plurality of exposed elongated areas is formed between adjacent elongated strips of masking material, such as wherein a plurality of exposed elongated areas within the plurality of exposed elongated areas is formed between adjacent elongated strips of masking material.

According to this embodiment, there is provided a plurality of elongated strips of masking material, such as 2, 3, 4, 5, 6, 7, 8, 9, 10, 50, 100 or 1000 elongated strips of masking material, and a plurality of exposed elongated areas, such as 2, 3, 4, 5, 6, 7, 8, 9, 10, 50, 100 or 1000 exposed elongated areas.

In an embodiment, there is provided a method for producing a substrate suitable for supporting an elongated superconducting element, where adjacent elongated strips of masking material within the plurality of elongated strips of masking material are substantially parallel with each other, such as parallel with each other. By ‘parallel’ may be understood parallel within 0, 1, 2, 3, 4, 5, 6, 7, 8, 9 or 10 degrees. It may be understood that the elongated strips may be piecewise parallel, such as the elongated strips themselves being non-rectilinear, such as curvilinear, such as piecewise linear, although immediately adjacent sections of masking material may still be parallel.

In an embodiment, there is provided a method for producing a substrate suitable for supporting an elongated superconducting element, wherein the solid element is an ellipsoidal cylinder, such as a circular cylinder. It may be understood that the geometric shape (such as ellipsoidal, such as circular) of the solid element, may refer to an outer shape of a cross-section of the cylinder, where the cross-section lies in a plane being perpendicular to the generating lines. It may be understood, that the solid element may have a length axis which is not necessarily parallel with the length axis of the elongated strips of masking material. In an embodiment, the solid element may have a length axis which is substantially perpendicular, such as perpendicular to a length axis of the elongated strips of masking material. This may, for example, be the case for a cylinder, where the length axis of the elongated strips of masking material is along a surface of the cylinder around a center axis of the cylinder along the axis of the cylinder. In another embodiment, the solid element may have a length axis which is substantially parallel, such as parallel to a length axis of the elongated strips of masking material.

In an embodiment, there is provided a method for producing a substrate suitable for supporting an elongated superconducting element, wherein a distance (752) between adjacent elongated strips of masking material within the plurality of elongated strips of masking material is within 1 micrometer-10 millimeter, such as 1 micrometer-4 millimeter.

In an embodiment, there is provided a method for producing a substrate suitable for supporting an elongated superconducting element, wherein a distance (752) between adjacent elongated strips of masking material within the plurality of elongated strips of masking material is within 1 micrometer-1 millimeter, such as within 10-100 micrometer, such as within 0.1 nm-10 mm, such as within 1 nm-1000 micrometer, such as within 1 nm-100 micrometer, such as within 1 nm-10 micrometer, such as within 10 nm-1000 micrometer, such as within 10 nm-100 micrometer, such as within 10 nm-10 micrometer, such as within 100 nm-1000 micrometer, such as within 100 nm-100 micrometer, such as within 100 nm-10 micrometer, such as within 1-1000 micrometer, such as within 1-100 micrometer, such as within 1-10 micrometer, such as within 10-1000 micrometer, such as within 20-200 micrometer, such as within 100-1000 micrometer, such as less than 10 micrometer, such as less than 100 micrometer, such as less than 200 micrometer, such as less than 1000 micrometer, such as less than 10 mm. An advantage of having the distance between adjacent elongated strips of masking material within this range may be that it enables reducing AC losses. It is to be understood that the distance between adjacent elongated strips of masking material is to be measured in a direction being parallel to the surface of the solid element, and orthogonal to the direction of the elongated strips of masking material. The adjacent elongated strips of masking material may in particular embodiments be substantially parallel, such parallel.

In an embodiment, there is provided a method for producing a substrate suitable for supporting an elongated superconducting element, wherein a distance is given between a plane being tangential to upper surfaces of the one or more portions of filling material after the step of
Removing, such as removing by etching or dissolving, the one or more elongated strips of masking material so as to form one or more corresponding undercut volumes, where each undercut volume within the one or more undercut volumes is formed along a portion of filling material and between the portion of filling material and the solid element,
   and a plane being tangential to bottoms of volumes bounded on at least two sides, such as three sides, by the solid element and one or more adjacent portions of filling material, and wherein said distance is large enough so as to enable that a superconducting material placed on the substrate may have portions
on the bottoms of volumes bounded on at least two sides, such as three sides, by the solid element and one or more adjacent portions of filling material,
and/or
on the one or more portions of filling material,
   which portions of superconducting material are physically separated, such as physically separated due to the one or more undercuts. In embodiments, said distance is within 50 nm-10 micrometer, such as within 1-100 micrometer, such as within 0.1 nm -10 mm, such as within 1 nm-1000 micrometer, such as within 1 nm-100 micrometer, such as within 1 nm-10 micrometer, such as within 10 nm-1000 micrometer, such as within 10 nm-100 micrometer, such as within 10 nm-10 micrometer, such as within 0.1-1000 micrometer, such as within 0.1-1000 micrometer, such as within 0.1-100 micrometer, such as within 0.1-10 micrometer, such as within 1-1000 micrometer, such as within 1-10 micrometer, such as within 10-1000 micrometer, such as within 10-100 micrometer, such as less than 10 micrometer, such as less than 100 micrometer, such as less than 200 micrometer, such as less than 1000 micrometer, such as less than 10 mm. By said ‘bottom(s) of volumes’ may be understood the surface portions of the solid element corresponding to the areas previously occupied by the elongated strips of masking material, such as the areas adjacent to the portions of filling material. In embodiments said distance is within 0.1 nm to 1 mm, or within 50 nm-10 micrometer, or within 1-100 micrometer, or within 0.1 nm -10 mm, or within 1 nm-1000 micrometer, or within 1 nm-100 micrometer, or within 1 nm-10 micrometer, or within 10 nm-1000 micrometer, or within 10 nm-100 micrometer, or within 10 nm-10 micrometer, or within 0.1-1000 micrometer, or within 0.1-1000 micrometer, or within 0.1-100 micrometer, or within 0.1-10 micrometer, or within 1-1000 micrometer, or within 1-10 micrometer, or within 10-1000 micrometer, or within 10-100 micrometer, or less than 10 micrometer, or less than 100 micrometer, or less than 200 micrometer, or less than 1000 micrometer, or less than 10 mm.

The volumes between the portions of filling material may be referred to as ‘disruptive strips’. By ‘disruptive strip’ may be understood a line of lack of filling material, which separates filling material into elongated strips of filling material on both sides of the disruptive strip. A disruptive strip may be seen as a gap in an otherwise coherent filling material. If a coherent filling material, such as a coherent layer of filling material, is traversed by a disruptive strip, the continuity of the coherent filling material is thus disrupted into two separate (layers of) material, such as two portions of filling material.

In an embodiment, there is provided a method for producing a substrate suitable for supporting an elongated superconducting element wherein a distance between adjacent disruptive strips within a plurality of disruptive strips is within 0.1 micrometer-10 millimeter.

In an embodiment, there is provided a method for producing a substrate suitable for supporting an elongated superconducting element wherein a distance between adjacent disruptive strips within a plurality of disruptive strips is within 1 micrometer-1 millimeter In another embodiment, there is provided a method for producing a substrate suitable for supporting an elongated superconducting element wherein a width of the disruptive strips may be 1 micrometer, such as 2 micrometer, such as 5 micrometer, such as 10 micrometer, such as 30 micrometer, such as 100 micrometer, such as 1 mm, such as 4 mm, such as 5 mm, such as 10 mm, such as within 1 micrometer-1 mm, such as 1 micrometer-10 mm, such as 1 mm-10 mm. An advantage of having the width in this range may be that it enables physically separating layers deposited on the substrate. It is to be understood that the width is to be measured in a direction being parallel to the surface of the solid element, and orthogonal to the direction of the disruptive strips, such as the length direction of the elongated strips of masking material.

In an embodiment, there is provided a method for producing a substrate suitable for supporting an elongated superconducting element, wherein the method further comprises placing a layer of buffer material (640) on
the one or more portions of filling material (318a-c)
and/or on
one or more sides, such as all solid sides, of the volumes bounded on at least two sides, such as three sides, by the solid element and one or more adjacent portions of filling material.

In an embodiment, there is presented a method for producing an elongated superconducting element, wherein the method comprises the steps of producing a substrate suitable for supporting an elongated superconducting element according to the first aspect, such as the previously described embodiments, and wherein the method further comprises placing,
a layer of buffer material (640)
   on the one or more portions of filling material (318a-c)
   and/or
   on bottoms of volumes bounded on at least two sides by the solid element and one or more adjacent portions of filling material,
   of the substrate suitable for supporting an elongated superconducting element provided according to the first aspect, such as the previously described embodiments, and
a layer of superconducting material (642, 644, 646) on the buffer material,
so that the undercut volumes (332) serve to physically separate individual lines of superconducting material and/or buffer material.

In an embodiment, there is provided a method for producing a substrate suitable for supporting an elongated superconducting element, wherein the one or more portions of filling material, and optionally the substrate, is shaped so as to enable twist pitching, such as a ROEBEL configuration (cf., the reference “Supercond. Sci. Technol. 22 (2009) 034003” which is hereby incorporated by reference in entirety), such as a Conductor On Round Core (cf. the reference “Supercond. Sci. Technol. 27 (2014) 125008” which is hereby incorporated by reference in entirety), or such as a geometry that enables transposition of superconducting elements placed on said substrate. Said shaping may be given by a piecewise linear shape, such as a zig-zag shape.

According to a second aspect of the invention, there is provided a method for producing an elongated superconducting element, wherein the method according to the second aspect comprises the method according to the first aspect and wherein the method further comprises placing a layer of superconducting material (642, 644, 646)
on the one or more portions of filling material (318a-c)
and/or on
a bottom of volumes bounded on at least two sides, such as three sides, by the solid element and one or more adjacent portions of filling material,
so that the undercut volumes (332) serve to physically separate individual lines of superconducting material.

An advantage of placing a layer of superconducting material on the one or more portions of filling material and/or on the bottom of volumes may be that it enables providing a superconducting structure. An advantage of placing a layer of superconducting material on the one or more portions of filling material and/or on the bottom of volumes so that the undercut volumes serve to physically separate individual lines of superconducting material may be that it enables providing a plurality of lines of superconducting material which are physically separated and hence effectively reduce the AC losses. A possible advantage is that it enables low material consumption, since no superconducting material need to be removed in order to realize the physical separation. Furthermore, an advantage may be that it may enable a complete utilization of the width of the substrate suitable for supporting an elongated superconducting element since no material is effectively missing between adjacent parallel lines of superconducting material. According to a further embodiment, there is provided a plurality, such as two or more, of elongated superconducting elements (such as being based on the elongated substrate according to the first aspect), and they are assembled in a twist pitching configuration.

In an embodiment according to the second aspect, there is provided a method for producing an elongated superconducting element, wherein the method according to the second aspect comprises the method according to the first aspect, and wherein the method further comprises placing,
a. a layer of buffer material
   on the one or more portions of filling material
   and/or
   on bottoms of volumes bounded on at least two sides, such as three sides, by the solid element and one or more adjacent portions of filling material,
   of the substrate suitable for supporting an elongated superconducting element provided according to the first aspect, and
b. a layer of superconducting material on the buffer material,
so that the undercut volumes serve to physically separate individual lines of superconducting material and/or buffer material.

A possible advantage of placing a layer of buffer material on the one or more portions of filling material and/or on the bottom of volumes may be that it enables placing a layer of superconducting material on top of the buffer layer, where the superconducting properties of the superconducting layers are improved and/or protected by being placed on the buffer layer, as opposed to being placed directly on the one or more portions of filling material and/or on the bottom of volumes. More specifically, the superconducting material may be improved since the buffer material may provide a texture which is advantageous in terms of improving the superconducting properties of the superconducting material. For example, if a substrate has a relatively rough substrate, then placing a buffer layer on such substrate may enable achieving a roughness (of the buffer—and hence the surface on which a superconducting layer is to be placed) of, e.g., 0.1 nm_{RMS}-10 nm_{RMS}. More specifically, the superconducting material may be protected since the buffer material may provide a barrier against potentially harmful elements (in terms of superconducting properties), such as atoms, ions and/or molecules which could have diffused from the one or more portions of filling material and/or on the solid element and into the superconducting material, and thereby deteriorate the superconducting properties. An advantage of placing a layer of superconducting material on the buffer material may be that it enables providing a superconducting structure. An advantage of doing it so that the undercut volumes serve to physically separate individual lines of superconducting material and/or buffer material may be that it enables providing a plurality of lines of superconducting material which are physically separated and hence effectively reduce the AC losses. The thickness of the layer of the superconducting material (in a direction orthogonal to the plane of the upper layer and the lower layer) may be 100 nm, such as 1000 nm, such as 3 micrometer, such as 5 micrometer, such as 50 micrometer, such as 100 micrometer, such as within the range of 100 nm-3 micrometer, such as within a range of 100 nm-50 micrometer, such as within a range of 100 nm-5 micrometer. It is noted that an advantage of having relatively thin superconducting layers may be that too thick layers becomes brittle and may fracture upon bending/winding into e.g. a coil. Very thick superconductor layers (made of Rare earth based barium copper oxide, such as Yttrium barium copper oxide, a crystalline chemical compound with the formula YBa₂Cu₃O₇₋ₓ (YBCO)), are known to have a lower critical current density compared with thinner layers. Multilayers of YBCO with intermediate buffer layers is one method for producing an effective thick superconductor stack with an overall higher critical current. By Rare earth elements is understood Gd, Nd, Sm, Eu, Ey, Y.

It is understood, that in order to obtain the advantage of having electrically decoupling adjacent lines, it may not be necessary that the lines of layer of material which is superconducting when placed on the buffer material is itself physically separated from adjacent lines. It may be sufficient that lines of buffer material are separated so that the layer of superconducting material is only superconducting along (and above) the lines of buffer material, whereas the corresponding lines of material in between are not superconducting.

In an embodiment, there is provided a method for producing a substrate suitable for supporting an elongated superconducting element, such as a method for producing an elongated superconducting element, wherein the method further comprises placing, such as depositing, a layer of superconducting material on one or more portions of filling material and/or on the bottom of volumes of the layered solid element so that the undercut volumes serve to physically separate individual lines of superconducting material, and the method further comprising placing, such as depositing,
a layer of buffer material on the superconducting material, such as on top of the superconducting material, such as on the side of the superconducting material being away from the solid element.

Strong texture and epitaxial growth of e.g. superconducting YBCO may be difficult to obtain for very thick layers (such as 500 nm-5 μm or more than 5 micrometer or more than 7 μm thickness). It is noted that texture and epitaxial growth decay at high superconductor YBCO layer thicknesses. A possible advantage of placing an (extra) layer of buffer material on the superconducting material may be that the superconducting properties of an additional superconducting layer (deposited on top of the extra buffer layer) may be improved, since the (extra) buffer layer again increases the fraction of texture and level of epitaxial growth. Thus, a possible advantage of placing a layer of buffer material on the superconducting material may be that it enables forming a ‘stack’ of high quality superconducting films.

In a further embodiment according to the second aspect, there is provided a method for producing an elongated superconducting element, wherein the method according to the second aspect comprises the method according to the first aspect, wherein the step of placing, such as depositing, a layer of superconducting material (642, 644, 646) and/or a layer of buffer material (640) is a line-of-sight process, such as a physical vapour deposition process, such as a pulsed laser deposition process, such as RF sputtering, such as E-beam evaporation, such as Ion Beam Assisted Deposition (IBAD), such as Alternating Beam Assisted Deposition (ABAD).

By a ‘line-of-sight’ process is understood any process which enables depositing material only on positions of a substrate which may be seen along a straight line from another position, such as a position above the substrate. ‘Line-of-sight’ process is thus construed broadly to comprise processes where the deposited material follows straight lines prior to deposition and processes for deposition which has a similar effect. In a particular embodiment, the line-of-sight process is any one of die coating, bubble jet coating and ink-jet coating.

A possible advantage of using a line-of-sight process may be that it enables depositing material only outside of the undercut volumes, and thus enables in a simple step to simultaneously achieve deposition of material outside the undercut volumes and achieve that there is no deposition of material within the undercut volumes.

In particular embodiments, ‘line-of-sight’ is understood to be a process wherein the deposited material has its origin from a source and travels in a direct line therefrom to the position where it is deposited. In other words, there can only be deposited material on positions from which there can be drawn a straight line to the source which does not traverse any obstacles. In a particular embodiment, the source is above the undercut volumes. In another embodiment, the source is so far above the lower layer, that virtual lines from the source to different positions on the substrate, such as positions within the undercut volumes are substantially parallel.

In an embodiment according to the second aspect, there is provided a method for producing an elongated superconducting element, wherein the method according to the second aspect comprises the method according to the first aspect and wherein the method is further comprising placing a shunt layer on the layer of superconducting material (642, 644, 646).

By a ‘shunt layer’ is understood a layer of material which is placed on the layer of superconducting material, which has high thermal conductivity and high electrical conductivity. An advantage of having a shunt layer may be, that if the an underlying superconductor does not conduct well at a certain point, the current may pass this (low conductivity) point via the (high conductivity) shunt layer thereby avoiding a failure of the structure due to resistive heating. Exemplary materials of the shunt layer may comprise silver (Ag) and/or copper (Cu and/or gold (Au). The shunt layer is not chemically active with respect to the layer of superconducting material, or the shunt layer is not typically chemically active with respect to the layer of superconducting material. The undercut volumes may be advantageous with respect to the shunt layer as the undercut volumes associated with the disruptive strips may also physically separate the shunt layer, such as physically separate the shunt layer material on either side of each disruptive strip and shunt layer material within the disruptive strip, thereby effectively forming a striated shunt layer, such as turning the shunt layer into stripes of shunt layer material. An advantage of forming a striated shunt layer may be that it enables removing high conductivity contact (through the shunt layer) between the lines of superconducting material, which is also separated by the undercut volumes, while still being able to thermally conduct to the outer supporting structure and allowing current to pass potential points of low conductivity (in parallel with the normal current direction) thus both enabling normal cooling and protection of the superconductor in the event of a quench. The shunt layer may be placed on the superconducting material with methods known in the art, such as by deposition, sputter deposition, electrochemical deposition, galvanic deposition, or similar methods. In alternative embodiments, the shunt layer is chemically active.

A capping layer may be understood as a layer yielding mechanical strength and/or further improving the thermal properties. A capping layer may typically comprise copper (Cu). It may in general be understood that the advantages described above in connection with striation/physical separation may also apply to capping layers. Thus, it may be seen as advantageous to have undercuts enabling physical separation of shunt layers and/or capping layers.

An advantage of forming a shunt layer and/or capping layer may be that such layer(s) may function as a mechanically stabilizing layer and/or as a layer improving the thermal properties, such as the shunt layer functioning as a thermally conducting layer, which may, e.g., facilitate conduction excess heat in case of a thermal quench (which in turn may thus serve to prevent or avert that a superconductor based on the substrate may become too hot and possibly even break down or burn due to overheating).

In another embodiment, there is provided a method for producing a substrate suitable for supporting an elongated superconducting element, such as a method for producing an elongated superconducting element, wherein the method further comprises introducing virtual cross-cuts in the substrate, the buffer layer and/or the superconducting material. Such virtual transverse cross-cuts may be beneficial for reducing AC loss. Virtual transverse cross-cuts are described in the reference “AC Loss Reduction in Filamentized YBCO Coated Conductors With Virtual Transverse Cross-Cuts”, Zhang et al., IEEE TRANSACTIONS ON APPLIED SUPERCONDUCTIVITY, VOL. 21, NO. 3, Jun. 2011, 3301-3306, which is hereby incorporated by reference in entirety.

According to a third aspect of the invention, there is provided a substrate suitable for supporting an elongated superconducting element, the substrate comprising:
A solid element,
One or more portions of filling material on the solid element and arranged so that a plurality of undercut volumes is formed along each portion of filling material and between the portion of filling material and the solid element.

In an embodiment, there is provided a substrate (300) suitable for supporting an elongated superconducting element, wherein the substrate is chosen from the group comprising: tape, roll, drum and reel. In an embodiment there is provided a substrate (300) suitable for supporting an elongated superconducting element, wherein the substrate is a tape.

In an embodiment, there is provided a substrate suitable for supporting an elongated superconducting element, comprising a plurality of portions of filling material, such as at least 3 portions of filling material, wherein a length of the substrate is at least 1 m, such as at least 10 m, such as at least 100 m, such as at least 1 km, such as at least 10 km, such as at least 100 km, such as at least 100 km. An advantage of having a relatively great length of the substrate may be that it enables forming a superconductor via the substrate, which enable conducting current across correspondingly great distances.

In an embodiment, there is provided a substrate suitable for supporting an elongated superconducting element, wherein the filling material is a homogeneous material.

By ‘wherein the filling material is a homogeneous material’ may be understood, that the filling material is a homogeneous type of material, such as the filling material is not a layered material where structure and/or composition depends on the distance to the solid element, such as the structure and composition at one position is similar to structure and composition at another position (for example the two positions being spatially separated along an axis being orthogonal to a surface of the solid element), such as a material which does not differ in one or more of structure (e.g., degree of crystallinity and/or type of crystal structure) and/or composition (e.g., chemical composition, such as elemental composition), such as when going along an axis being orthogonal to the solid element. It may be understood as is common in the art, that ‘homogeneous’ encompasses mixtures of materials on a microscopic scale where the components does not appear in layered form, for example an alloy might be homogeneous or might contain small particles, such as components that can be viewed with a microscope. It may be understood that the wording ‘wherein the filling material is a homogeneous material’ encompasses embodiments wherein one or more undercut volumes is formed along said homogeneous portion of filling material and between the homogeneous portion of filling material and the solid element (in other words: Said wording does not exclude that a homogeneous portion of filling material with an associated undercut is coated with another layer, (thereby forming a seemingly inhomogeneous structure, e.g., a layered structure), as long as the homogeneous portion alone forms a filling material with an associated undercut).

In an embodiment, there is provided a substrate suitable for supporting an elongated superconducting element, comprising a plurality of portions of filling material, such as at least 3 portions of filling material, being substantially parallel, such as parallel with each other, and wherein one or more portions of a surface of the solid element, such as an upper surface 314, upon which the filling material is placed, said one or more portions of said surface being placed between said portions of filling material, is/are substantially planar, such as planar, such as having a radius of curvature being larger, such as 2, 3, 4, 5, 10, 20, 50, 100 times larger, than a distance between neighbouring portions of filling material, such as an upper edge when observed in a cross-section being orthogonal to a length direction of said substrate having a radius of curvature being larger, such as 2, 3, 4, 5, 10, 20, 50, 100 times larger, than a distance between neighbouring portions of filling material. A possible advantage of having said one or more portions of said surface being placed between said portions of filling material substantially planar, such as planar, may be, that it facilitates providing said portions of said surface with a low surface roughness, which may in turn be beneficial for the electrical properties of a subsequently deposited superconducting layer.

In an embodiment, there is provided a substrate suitable for supporting an elongated superconducting element, comprising a plurality of portions of filling material, such as at least 3 portions of filling material, being substantially parallel, such as parallel with each other, and wherein a surface of the solid element, such as an upper surface, upon which the filling material is placed, is substantially planar, such as planar, such as having a radius of curvature being larger, such as 2, 3, 4, 5, 10, 20, 50, 100 times larger, than a distance between neighbouring portions of filling material, such as an upper edge when observed in a cross-section being orthogonal to a length direction of said substrate having a radius of curvature being larger, such as 2, 3, 4, 5, 10, 20, 50, 100 times larger, than a distance between neighbouring portions of filling material. A possible advantage of having said surface being substantially planar, such as planar, may be, that it facilitates in a simple way providing portions of said surface being placed between or adjacent one or more portions of filling material which are planar, which in turn facilitates providing said portions of said surface with a low surface roughness, which may in turn be beneficial for the electrical properties of a subsequently deposited superconducting layer. The surface of the solid element may have portions (or areas) below and between portions of filling material, which portions or areas are flush with each other. By ‘flush’ may be understood that the different portions or areas of the surface together form a surface without bends, breaks, or irregularities, such as a substantially planar surface, such as a planar surface.

In an embodiment, there is provided a substrate suitable for supporting an elongated superconducting element, comprising a plurality of portions of filling material, such as at least 3 portions of filling material, wherein the substrate is a tape, wherein the length of the substrate is at least 1 m, wherein the filling material is a homogeneous material, and wherein said substrate is comprising a plurality of portions of filling material being substantially parallel, and wherein one or more portions of a surface of the solid element, upon which the filling material is placed, said one or more portions of said surface being placed between said portions of filling material, is/are substantially planar.

According to a fourth aspect of the invention, there is provided an elongated superconducting element comprising:
A substrate according to the third aspect of the invention,
a superconducting layer placed, on the substrate or on a buffer on
the substrate, so that the undercut volumes (332) physically separates individual lines of superconducting material or so that the undercut volumes (332) serve to physically separate individual lines of superconducting material and/or buffer material.

According to a fifth aspect of the invention, there is provided an apparatus for carrying out the method according to the third and/or fourth aspect of the invention.

According to a sixth aspect of the invention, there is provided use of an elongated superconducting element according to the fourth aspect of the invention and/or an elongated superconducting element (601) produced according to the second aspect, within any one of a performance magnetic coil, a transformer, a generator, a motor, an electro-motor, a magnetic resonance scanner, a cryostat magnet, a large hadron collider, an AC power grid cable, a DC power grid cable, a smart grid, tokamak.

The first, second, third, fourth, fifth, and sixth aspect of the present invention may each be combined with any of the other aspects. These and other aspects of the invention will be apparent from and elucidated with reference to the embodiments described hereinafter.

### BRIEF DESCRIPTION OF THE FIGURES

The first, second, third, fourth, fifth and sixth aspects according to the invention will now be described in more detail with regard to the accompanying figures. The figures show one way of implementing the present invention and is not to be construed as being limiting to other possible embodiments falling within the scope of the attached claim set.

FIG. 1 shows a typical superconductor structure,

FIG. 2 illustrates a non-striated (a) and a striated (b) superconductor,

FIG. 3 shows steps of a fabrication process,

FIGS. 4-5 shows steps in an alternative fabrication process,

FIG. 6 shows steps of a fabrication process,

FIG. 7 illustrates dimensions of disruptive strips,

FIG. 8 illustrates dimensions of a superconducting structure,

FIGS. 9-10 are top views showing portions of filling material shadowing undercuts,

FIGS. 11-12 are cross-sections of a solid element with masking- and filling material,

FIG. 13 corresponds to FIGS. 11-12 after removal of masking material,

FIG. 14 is a cross-section of a sample where Ag is deposited over an undercut,

FIG. 15 shows an apparatus for carrying out the method according to the first aspect.

FIG. 16 illustrates a process flow according to an embodiment,

FIG. 17-18 show samples prepared according to embodiments,

FIG. 19 illustrates a process flow according to an embodiment,

FIG. 20 shows a sample prepared according to an embodiment,

FIG. 21 illustrates a process flow according to additional steps.

### DETAILED DESCRIPTION OF AN EMBODIMENT

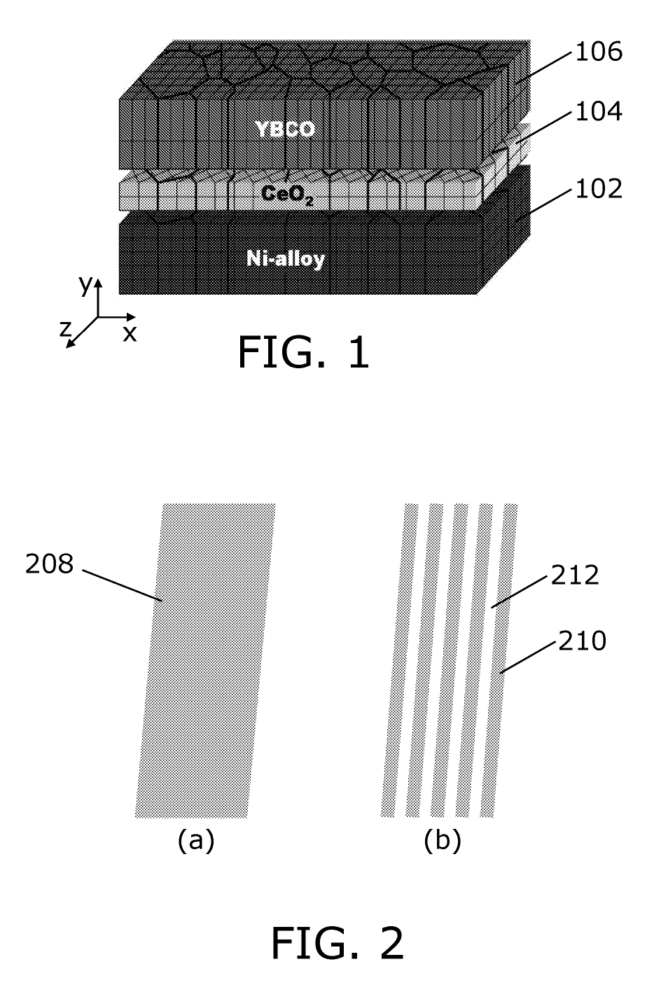

FIG. 1 shows a typical superconductor structure, which is a sandwich structure comprising a substrate 102, a buffer and the superconducting material 106. In the present figure, the current is supposed to flow through the superconducting material 106 in the z-direction.

When the superconducting material is a relatively wide (where width is measured in the x-direction) layer of material, such as when formed as a layer on a wide planar substrate, the superconducting layer exhibits relatively large AC losses which could be reduced by turning the single, wide superconducting layer into a plurality of relatively narrow lines (i.e., lines with cross-sections in the yx-plane where the widths measured in the x-direction are smaller compared to the original, wide layer).

FIG. 2 is a top view of a superconducting material, where the left side (a) illustrates a non-striated superconductor 208 formed on a planar layer, and the right side (b) illustrates a striated superconductor, where individual lines 210 of superconducting material have been formed are separated from adjacent lines of superconducting material by non-superconducting lines 212. It is understood that current runs in a direction parallel to the lines, and that the width is the dimension of the lines in a direction orthogonal to the direction of the current.

Due to electromagnetic effects, AC losses are present in superconducting tapes, and this problem scales with the width of the superconductor. Consequently, it is suggested to overcome this problem by replacing the wide superconductor layer (corresponding to the superconductor layer in FIG. 2(b)) by a plurality of thin superconductor lines (corresponding to the separated, adjacent lines in FIG. 2(a)).

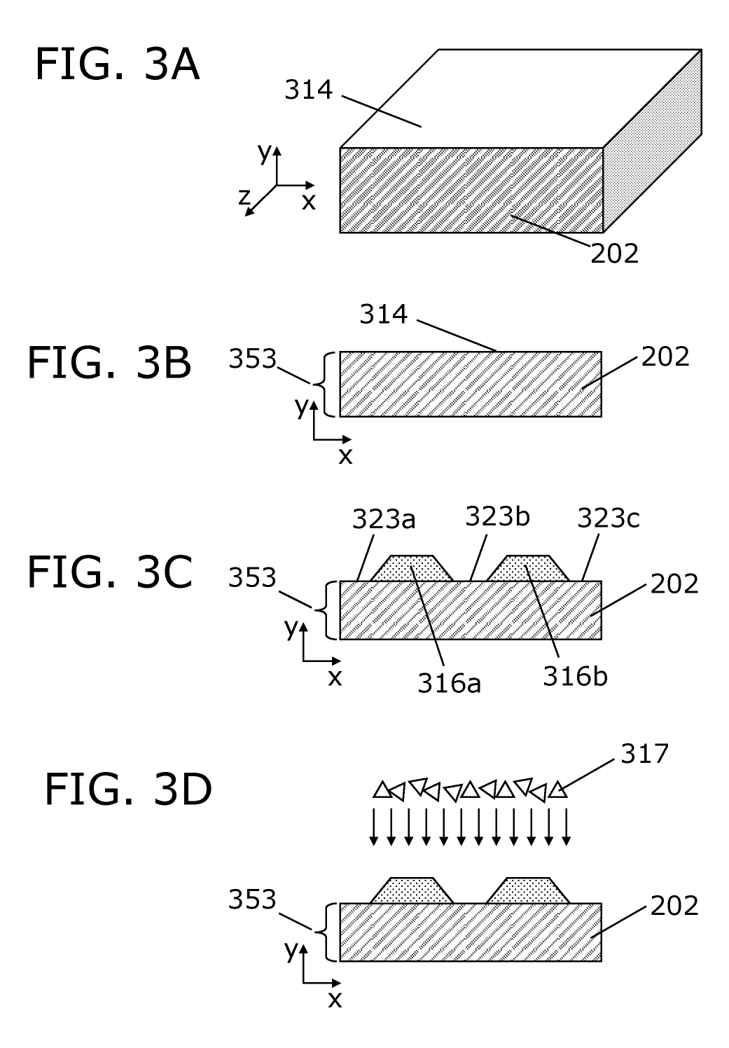

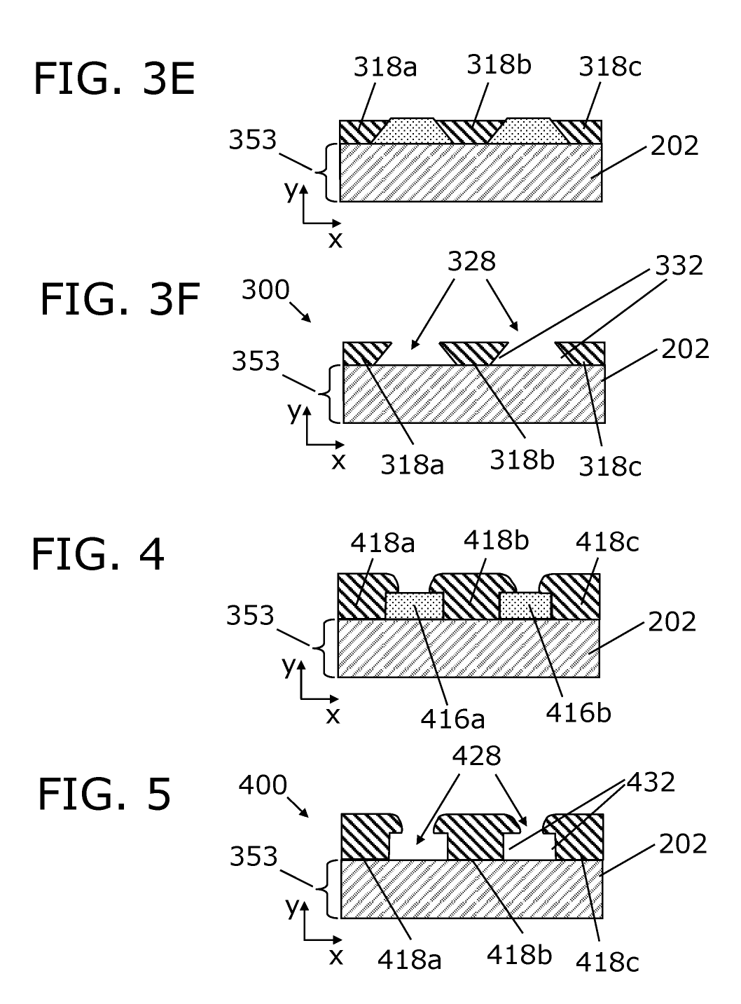

FIG. 3 shows steps of a fabrication process, and thus illustrates a method for producing a substrate suitable for supporting an elongated superconducting element, such as a superconducting tape having reduced AC losses.

FIG. 3A shows a perspective view of a solid element 202, the solid element 202 having an upper surface 314 being substantially uniform.

Generally, the solid element material (tape/wire/cylinder) in an as-rolled (or as-prepared) condition and e.g. with a thickness close to the final thickness may be fully or partially annealed during a heat treatment in a protective atmosphere or air.

FIG. 3B shows a side view of the solid element where the side of the solid element 202 can be seen. The thickness 353 (extension along a first dimension, which is in the y-axis) of the solid element 202 may be significantly smaller, such as 10, 100 or 1000 times smaller, than its width (extension along a second dimension, which is parallel to the x-axis) and where the width is significantly smaller, such as 10, 100, or 1000 times smaller, than length (extension along a third dimension, which is parallel to the z-axis). The thickness 353 may in exemplary embodiments be 10 micrometer, such as 20, such as 50 micrometer, such as 100 micrometer, such as 1 mm, such as within 10 micrometer-1 mm.

FIG. 3C shows the solid element 202 after a step of placing a plurality of elongated strips of masking material 316a, 316b on the solid element, where the elongated strips of masking material are arranged so as to form three exposed elongated areas 323a-c, where each exposed elongated area is delimited on one or two sides by at least one elongated strip of masking material. For example, the exposed elongated area 323a which is placed to the left is delimited on only one side by an elongated strip 316a of masking material and on the other side by an edge of the solid element 202. The exposed elongated area 323b which is placed in the middle is delimited on two sides by adjacent elongated strips 316a-b of masking material.

FIG. 3D-E shows placing filling material 317 on the solid element 202, more particularly on the surface 314 of the solid element. It may be understood that the filling material may be or is placed so as to form a homogeneous filling material.

FIG. 3E shows the situation after the step of placing filling material 317 on the solid element 202, more particularly on the surface 314 of the solid element, so that each exposed elongated area 323a-c is covered by a coherent portion of filling material, where each portion of filling material 318a-c also covers at least a portion of the adjacent elongated strip(s) of masking material. It may be understood that the filling material 318a-c may be homogeneous or is homogeneous. It appears from the figures, that the masking strips 316a-b have a trapezoidal shape which may aid in achieving that each portion of filling material also covers at least a portion of the adjacent elongated strip(s) of masking material. However, it is also encompassed that masking strips have other shapes, such as triangular, rectangular or circular.

FIG. 3F shows the situation where a substrate 300 suitable for supporting an elongated superconducting element has been provided after a step of removing the elongated strips of masking material 316a-b so as to form corresponding undercut volumes 332, where each undercut volume within the one or more undercut volumes is formed along a portion of filling material and between the portion of filling material and the solid element. The volumes 328 between the portions of filling material may be referred to as ‘disruptive strips’ 328. The undercut volumes 332 are positioned between the portions of filling material 318a-c and the solid element 202, such as the undercuts being regions which are above the surface of the solid element, but which are also shadowed when observed from above.

The resulting surface profile, cross-sectional profile and surface texture may be inspected using a means for measuring microtexture, such as a scanning electron microscope (SEM) equipped with an Electron Backscatter Diffraction Detector (EBSD) detector and which may in a particular embodiment employ software for measuring and analysing texture, such as HKL Technology-Channel 5 software. Note that texture measurements may only be necessary for textured substrate materials.

FIGS. 4-5 shows steps in an alternative fabrication process.

FIG. 4 shows a situation similar to FIG. 3E, except that the elongated strips of masking material 416a-b each have a rectangular (and not trapezoidal) cross-section, and furthermore, that the portions of filling material 418a-c extends above the masking material in the upwards y-direction, and partially over the masking material in the x-direction.

FIG. 5 shows a situation corresponding to FIG. 4 although the masking material has been removed (similar to FIG. 3F vs. FIG. 3E), i.e., a situation where a substrate 400 suitable for supporting an elongated superconducting element has been provided after a step of removing the elongated strips of masking material 416a-b so as to form corresponding undercut volumes 432. The volumes 428 between the portions of filling material may be referred to as ‘disruptive strips’ 428. Thus, even though the sides of the elongated strips of masking material are vertical, it may still be possible to realize the undercuts 432. In an embodiment, the elongated strips of masking material are striated Kapton® tape, where Cu has been placed on portions adjacent the edges of each strip of tape, which facilitates the embodiment in FIGS. 4-5, e.g., by means of electrodeposition of filling material.

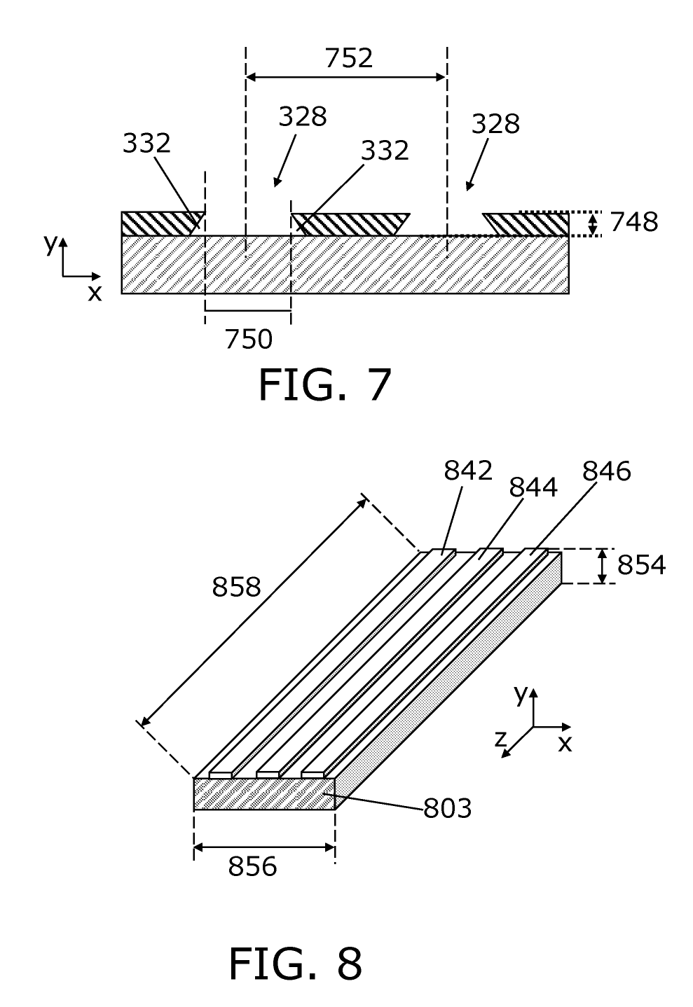

In each of FIG. 3F and FIG. 5, there is provided a substrate suitable for supporting an elongated superconducting element, comprising a plurality of portions of filling material (corresponding, respectively, to filling material 318a-c and filling material 418a-c) being substantially parallel, such as parallel with each other, and wherein a surface (surface 314 in FIG. 3B) of the solid element (202), such as an upper surface, upon which the filling material is placed, is substantially planar, such as planar, such as having a radius of curvature being larger than a distance (corresponding to distance 750 in FIG. 7) between neighbouring portions of filling material. The planarity may be seen as said surface of said solid forming a straight line when observed in a cross-section (as in each of FIG. 3F and FIG. 5) being orthogonal to a length direction (corresponding to the z-direction in each of FIG. 3F and FIG. 5) of said substrate, such as said straight line having a radius of curvature being larger, such as 2, 3, 4, 5, 10, 20, 50, 100 times larger, than a distance between neighbouring portions of filling material

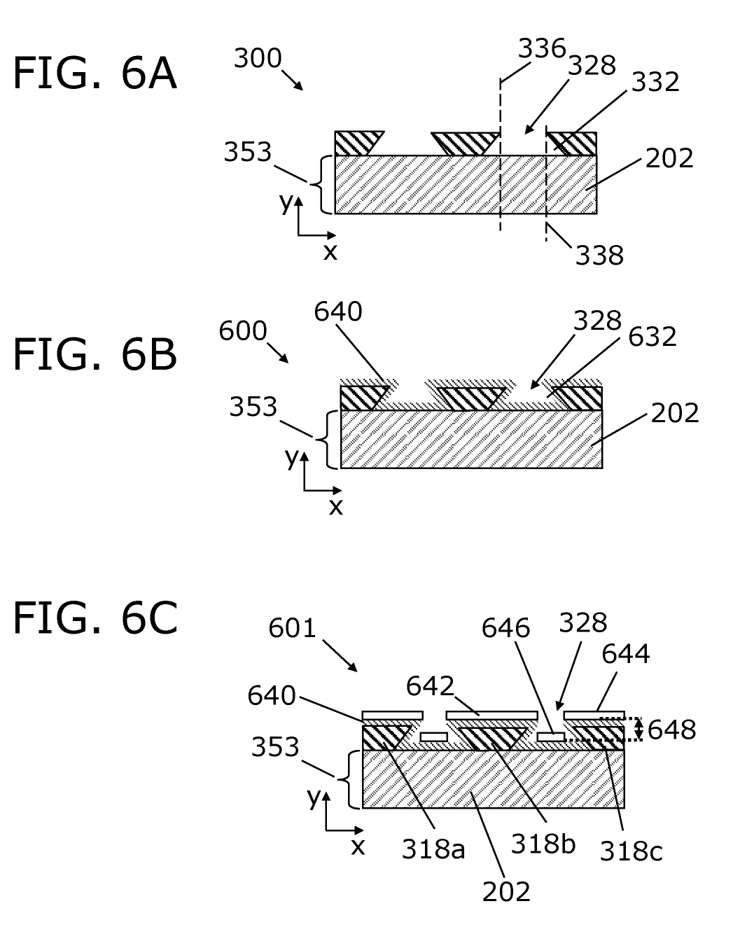

FIG. 6 shows steps of a fabrication process for producing an elongated superconducting element.

FIG. 6A shows a situation similar to the situation of FIG. 3F, i.e., a substrate 300 suitable for supporting an elongated superconducting element, where undercut volumes 332 are formed between the surface of the solid element 202 and the portions of filling material, such as indicated by the dotted lines 336, 338.

FIG. 6B shows placing, such as depositing, a layer of buffer material 640 on the substrate suitable for supporting an elongated superconducting element, more specifically one the portions of filling material and on the bottom of volumes bounded on three sides by the solid element and by adjacent portions of filling material, thereby forming an exemplary a substrate 600 suitable for supporting an elongated superconducting element, which substrate comprises a buffer layer 640. It is noted that undercuts 632 may still be present even after placement of the buffer layer.

A ceramic buffer layer stack (e.g. Y₂O₃/YSZ/CeO₂ for textured substrates) and superconducting layer (such as YBa₂Cu₃O₇) may be placed, such as deposited, such as deposited by pulsed laser deposition (PLD) using standard settings, on substrate 300 suitable for supporting an elongated superconducting element.

FIG. 6C shows placing a layer of superconducting material 642, 644, 646 on the buffer material, so that the undercut volumes serve to physically separate individual lines of superconducting material. It is understood that the distance 648 between a bottom of the disruptive strips (incl. buffer layer) and the upper surface of the portions of filling material (incl. buffer layer) is large enough so as to ensure that the separate portions 642, 644, 646 of layer of superconducting material on the buffer material is physically separated.

The deposition of ceramic buffer layers and superconducting layer (where at least one layer is deposited by a physical vapour technique/directional deposition) will only deposit material on the horizontal surfaces of the substrate. A complete strip decoupling is achieved via the undercut portions, and furthermore material usage is minimized. Additional layers (silver/copper) added on top of the superconductor layer will also be decoupled.

The performance of the superconducting material with respect to critical current density (J_{c}), critical current (I_{c}), AC-losses (W) and frequency dependency (f_{d}) may be measured by vibrating sample measurements, AC loss measurements (calorimetric or phase-shift measurements), and transport measurements on small model samples (5×5 mm²) and 15 cm long samples at various applied magnetic fields and temperatures. A full scale superconductor tape, such as one or more meters of superconductor tape, may be wound into a coil and tested at 77 K applying various magnetic fields and transport currents. The performance of the superconducting material may furthermore be quantified via Hall-probe measurements enabling determining magnetization within the striated superconductor elements.

It is noted, that a possible advantage of embodiments of the invention may be, that a larger critical current (I_{c}) may be supported for a structure having a certain width. An explanation of this is that the total width (extension along the x-axis) of the separate portions 642, 644, 646 of layer of superconducting material is relatively large compared to prior art solutions where material between lines of superconducting material is made non-superconducting, cf., the embodiment shown in FIG. 2, where the total width of the striated superconductor (in FIG. 2(b)) is approximately half the width of the non-striated superconductor (in FIG. 2(a)). In comparison, with embodiments of the present invention, the total width of the striated superconductor may be more than 0.5, 0.6, 0.7, 0.8, 0.9 or 0.95 or 0.99 times the width of the non-striated superconductor, since the superconducting material may be placed both between and within disruptive strips.

FIG. 7 illustrates dimensions of the disruptive strips 328. The figure shows a situation similar to FIG. 3F or FIG. 6A. Furthermore is indicated a distance 748 between a plane being tangential to upper surfaces of the one or more portions of filling material and a plane being tangential to bottoms of volumes bounded on three sides by the solid element and adjacent portions of filling material. Said distance 748 may preferably be non-zero and below 4 mm, such as]0; 4[mm, or non-zero and below 1 mm, such as]0; 1[mm. Furthermore is indicated a width 750 of the disruptive strips (in the filling material) measured in the x-direction, the width may in exemplary embodiments, be 1 micrometer, such as 2 micrometer, such as 5 micrometer, such as 10 micrometer, such as 30 micrometer, such as 100 micrometer, such as 1 mm, such as within 1 micrometer-1 mm. Furthermore is indicated a distance 752 between adjacent disruptive strips within the plurality of disruptive strips which is measured in the x-direction.

FIG. 8 illustrates dimensions of a superconducting structure which has thickness 854 (length along a first dimension, which is in the y-axis) which is significantly smaller, such as 10, 100 or 1000 times smaller, than its width 856 (length along a second dimension, which is parallel to the x-axis) and where the width 856 is significantly smaller, such as 10, 100, or 1000 times smaller, than (length along a third dimension, which is parallel to the z-axis). The figure furthermore shows three layers, such as lines 842, 844, 846, of superconducting material on top of the substrate. The thickness 854 may in exemplary embodiments be 10 micrometer, such as 20 micrometer, such as 50 micrometer, such as 100 micrometer, such as 1 mm, such as within 10 micrometer-1 mm. The width 856 may in exemplary embodiments may in particular embodiments be 1 micrometer, such as 10 micrometer, such as 100 micrometer, such as 1 mm, such as 10 mm, such as 100 mm, such as 1 m, such as within 1 micrometer-1 m. The length 858 may in particular embodiments be 1 m, such as 100 m, such as 1 km, such as 20 km, such as 100 km, such as above 100 km, such as within 1 m-30 km, such as within 1 km-30 km. The superconducting structure may be based on a solid element 803 in the shape of a tape. The length may be at least 1 m, such as at least 10 m, such as at least 100 m, such as at least 1 km, such as at least 10 km, such as at least 100 km, such as at least 100 km. It may be understood, that the lengths of one or more or all of the elements optionally placed on the substrate, such as elongated strips of masking material, filling material, buffer, superconducting material, shunt layer may have a length being similar to or identical to the length of the substrate.

### EXAMPLES

### Example A

In an exemplary embodiment according to the invention, there may be provided a substrate suitable for supporting an elongated superconducting element according to the following protocol, which protocol describes copper plating strips with a shadow-profile on Hastelloy C276 metal tapes.
1) The solid element is provided in form of a metal tape (Hastelloy C276) which is cleaned applying an alkaline soak, or alternatively, 5 min cleaning in acetone with ultrasound and then 5 min in ethanol with ultrasound.
2) Placing one or more strips of masking material is carried out with Kapton® masking tape which is applied in parallel strips on the up side of the metal tape and smoothened so that there are no air bubbles between the Kapton® tape and the metal tape. The edges of the Kapton® tape are cut so that the down side of the tape (glue side) is wider than the up side and preferably so that one or both edges make an angle of about 45° with the tape plane (e.g., such as depicted in FIG. 3C).
3) The down side of the metal tape is covered completely (non-filamented) with Kapton® tape and smoothened to avoid air bubbles.
4) Acid dip in HCl (20%) for 5 sec.
5) Anodic etch (“+” on metal tape) in Wood's nickel strike solution (solution example: 5 g NiCl₂, 10 ml HCl (37%), 100 ml H₂O), 53 mA/cm² for 20-30 sec at 38° C. Do not take the sample out of the solution.
6) Placing filling material on the solid element is carried out by nickel plating (cathodic, i.e. “−” on metal tape) using Wood's nickel strike solution, 53 mA/cm² for 2-3 min.
7) Rinse with water and proceed immediately to the copper plating procedure.
8) Copper plating in cathodic (“−” on metal tape) setup. Solution example 24 g CuSO₄, 6 g H₂SO₄, HCl 25 μl and 100 ml ion-free water. Operation temperature=20° C. and current density=83 mA/cm² for 3-15 min (it may be noted that the present steps 7-8 may be seen as optional, since it may be possible to exclusively rely on electrodeposition of nickel, and thereby render the copper electrodeposition superfluous).
9) Rinse the coated tape with water.
10) Removing the strips of masking material is carried out by immersing the coated tape in acetone with ultrasound for about 5 min and then 5 min in ethanol with ultrasound. The Kapton® tape can then easily be peeled of using a tweezer. Rinse again using acetone and ethanol for a few minutes.
11) Dry the tape using flowing nitrogen.

### Results

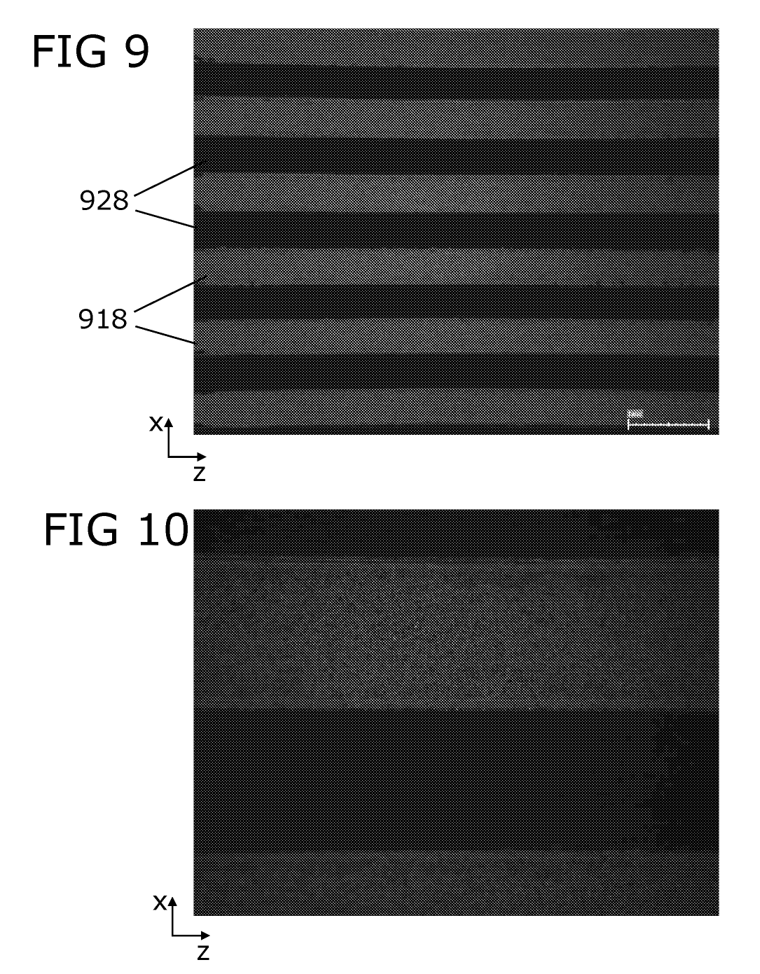

FIG. 9 shows the resulting portions 918 of filling material which shadows undercuts below a sub-portion of the portions of filling material as observed with optical microscopy. The disruptive strips 928 are also indicated. The scale bar is 1 mm, so the widths of the portions 918 of filling material are approximately 0.4 mm, and the widths of the disruptive strips 928 are approximately 0.4 mm.

FIG. 10 is similar to FIG. 9 albeit at a larger magnification.

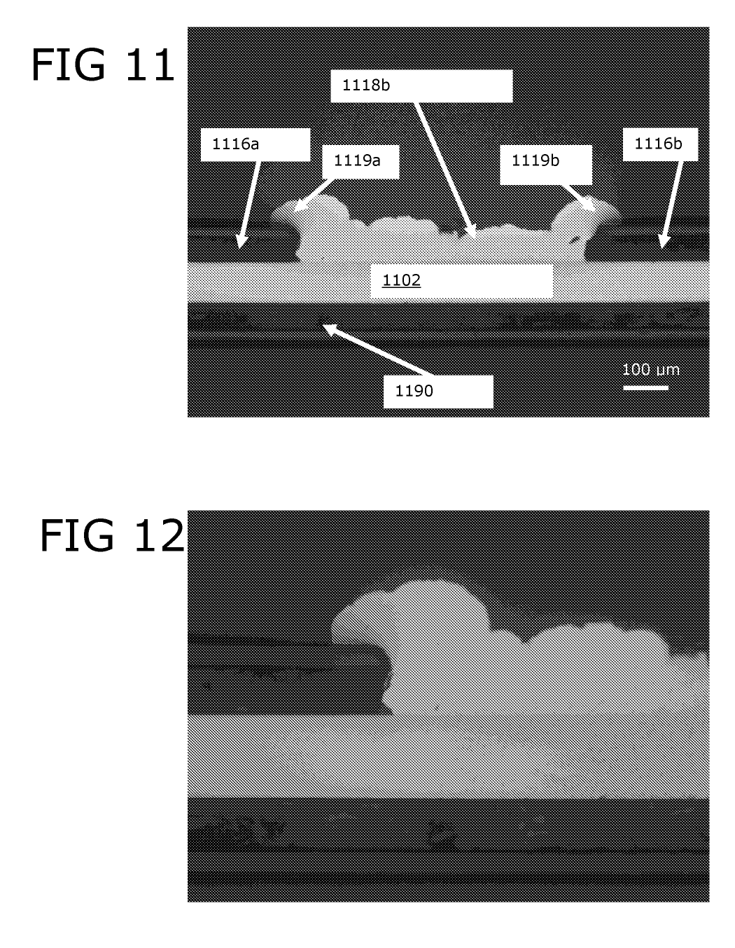

FIGS. 11-13 are cross-sectional views of a sample prepared according to the protocol of Example A, but with a tape which cut with a 90° angle and not cut with a 45° angle as suggested as preferable stated in example A. step 2.

FIG. 11 is a cross-section of a solid element with masking- and filling material. The image thus corresponds to FIG. 3E or FIG. 4. More particularly, FIG. 11 is an optical image of the cross-section of a selectively copper-plated Hastelloy C276 tape where the protective Kapton® tape is not removed. The figure shows a solid element 1102 (being the Hastellogy C276 tape) after a step of placing a plurality of elongated strips of masking material 1116a, 1116b on the solid element (the masking material being elongated strips of Kapton® tape), where the elongated strips of masking material are arranged so as to form an exposed elongated area between the elongated strips of masking tape 1116a-b, where the exposed elongated area is delimited on two sides by adjacent elongated strips 1116a-b of masking material. Furthermore, the figure shows that a portion filling material 1118b has been placed on the solid element 1102, more particularly on the surface of the solid element corresponding to the exposed elongated area, where the filling material is electrodeposited copper, so that the exposed elongated area is covered by a coherent portion of filling material, where the portion of filling material 1118b also covers at least a portion of the adjacent elongated strips of masking material, cf., e.g., the overhanging portions 1119a-b of copper. Thus, an overhang of electroplated copper is clearly present on top of the protective Kapton® tape. The Kapton® tape is placed on both sides of the Hastelloy tape to control where electroplated material is deposited (cf., the elongated masking strips of masking material 1116a-b on the upper side, and the masking material 1190 on the lower side which is also Kapton® tape). The scalebar is 100 μm.

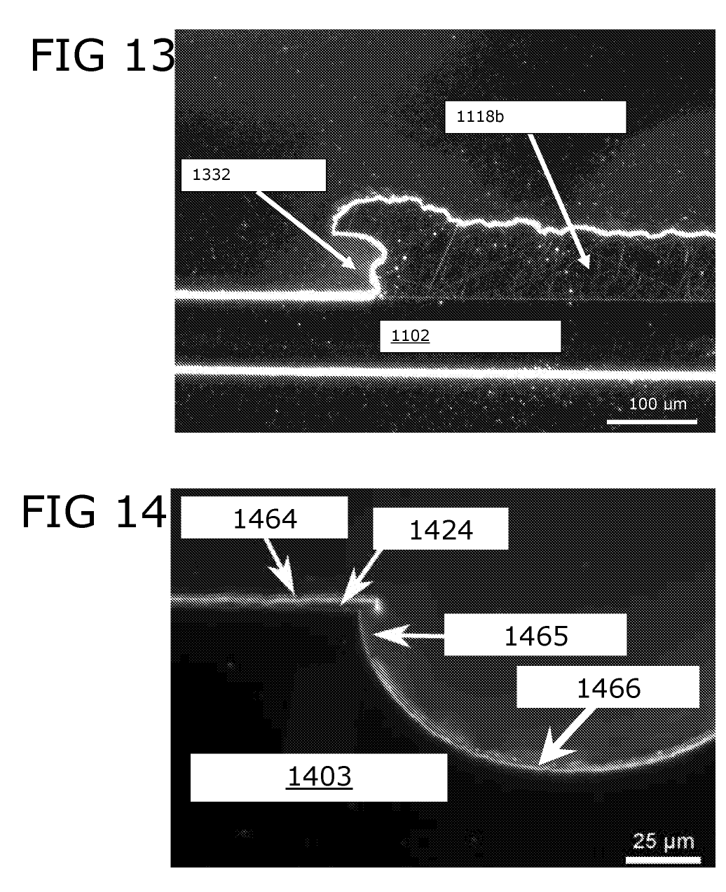

FIG. 12 similar to FIG. 11 albeit at a larger magnification.

FIG. 13 corresponds to FIGS. 11-12 after removal of masking material. The image thus corresponds to FIG. 3F or FIG. 5. More particularly, the figure shows an optical image of the cross-section of a selective copper-plated Hastelloy C276 tape where the protective Kapton® tape has been removed following the instructions described in example A. FIG. 13 shows a situation where the substrate suitable for supporting an elongated superconducting element has been provided after a step of removing the elongated strips of masking material so as to form a corresponding undercut volume 1332, where each undercut volume within the one or more undercut volumes is formed along a portion of filling material and between the portion of filling material and the solid element. The undercut volumes 332 are positioned between the portions of filling material 1118b and the solid element 1102, such as the undercuts being regions which are above the surface of the solid element, but which are also shadowed when observed from above. An undercut volume is clearly seen between the Hastelloy tape and the electroplated copper. The Hastelloy tape is approximately 100 μm thick and the undercut volume extends about 50 μm from the bulk part of the electroplated copper. The scalebar is 100 μm.

An apparatus for carrying out the method according to the first aspect, more specifically for carrying out the process described in Example A above:

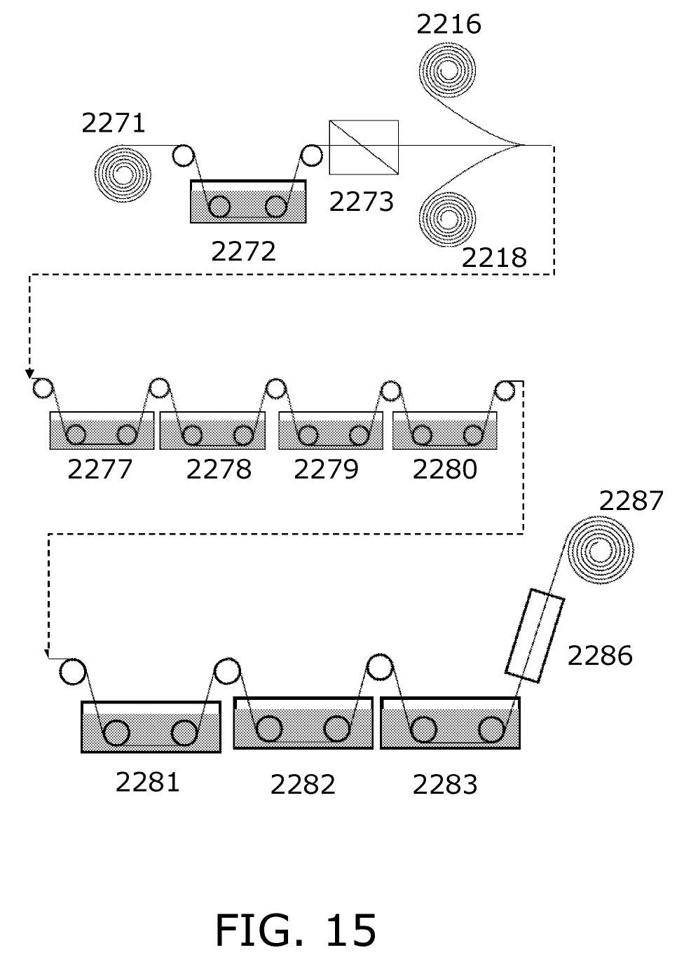

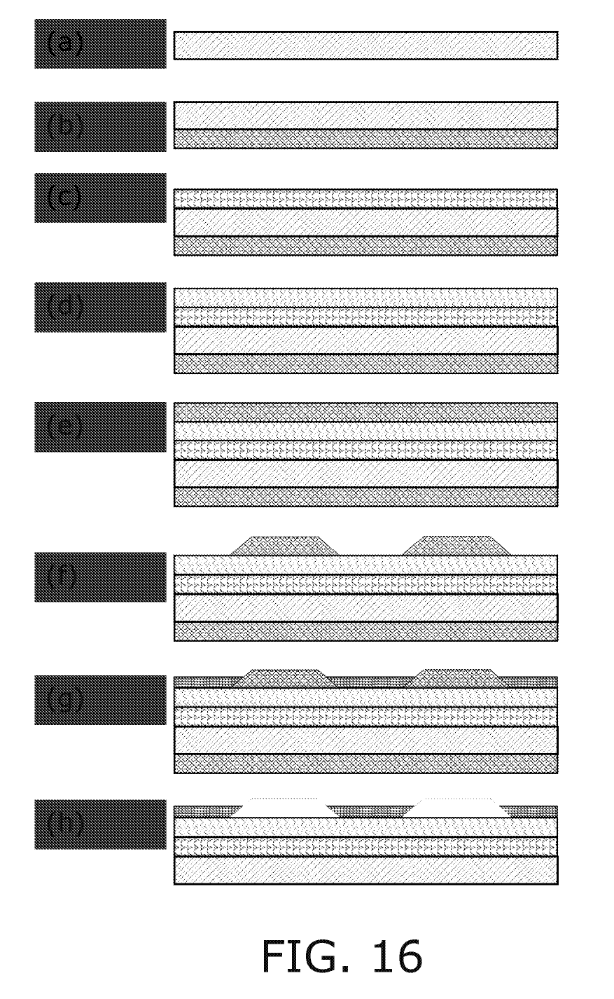

FIG. 15 shows an apparatus for, such as arranged for, carrying out the method according to the first aspect, such as an apparatus arranged for carrying out the protocol as described above in connection with Example A. The figure shows a reel-to-reel system, where a metal tape is transferred from a first reel 2271 to a second reel 2287, and in the process is transformed into a substrate suitable for supporting an elongated superconducting element by going through an ultrasound cleaning bath 2272 comprising acetone and/or ethanol (this bath step may be replaced by or be supplemented with an alkaline soak cleaner), a dryer 2273 using air or nitrogen (N₂), a set of reels comprising an upper reel 2216 and a lower reel 2218. The upper reel comprises filamented masking tape, i.e., the tape material is capable of acting as masking material, which tape has been sectioned into elongated strips of masking material, which elongated strips of masking material are transferred from the reel 2216 to an upper side of the tape so as to place elongated strips of masking material and thereby form exposed elongated areas (corresponding to step 2 of the protocol in Example A). The lower reel 2218 comprises masking tape which is not filamented so that the masking tape may completely cover a lower side of the metal tape (corresponding to step 3 of the protocol in Example A), where a possible advantage of this may be, that during subsequent placement of filling material on non-masked areas, no filling material is placed on the backside, where it would serve no purpose). Note that the metal tape continues as indicated by the dashed line and the metal tape then proceeds through an acid dip bath 2277 with (HCl) (corresponding to step 4 of the protocol in Example A), an anodic etch and nickel plating bath 2278 with Woods nickel strike solution (corresponding to steps 5-6 of the protocol in Example A), a cleaning bath 2279 with water (corresponding to step 7 of the protocol in Example A), a copper plating bath 2280 with a solution as described in step 8 of the protocol in Example A—where it may be noted that the steps 7-8 in the protocol in Example A may be seen as optional and that consequently cleaning bath 2279 and copper plating bath 2280 are also optional (note that the tape continues as indicated by the dashed line), a cleaning bath 2281 with water (corresponding to step 9 of the protocol in Example A), an ultrasound cleaning bath 2282 comprising acetone and an ultrasound cleaning bath 2283 comprising ethanol (corresponding to step 10 of the protocol in Example A), a dryer 2286 using air or nitrogen (N₂) (corresponding to step 11 of the protocol in Example A), and finally the second reel 2287.

### Example B

A layer of masking material is provided by a protective layer, such as a standard imprint resist or photoresist for UV lithography, a Kapton® film or scotch tape.

The layer of masking material of e.g. photoresist (produced e.g. using die slot coating or dip coating) or Kapton® film, or imprint resist or scotch tape is applied to the sample surface (i.e., to the surface of the solid element). Forming elongated strips of masking material is carried out by cutting or roll-cutting lines into the layer of masking material and subsequently removing, e.g., every second of the thin strips of layer of masking material so that the surface of the solid element is (partially) covered by parallel but separated, elongated strips of masking material, e.g. strips of Kapton® film.

### Example C

The starting material, such as the solid element (e.g. a Hastelloy tape), is coated with elgonated strips of masking material, such as with Kapton® film (or wax or lacquer) in stripes parallel to the length of the metal tape. The stripes should be e.g. 1 mm wide and positioned with a spacing of, e.g., 1 mm. Notice that the Kapton® film may be firmly attached to the sample, e.g. using a brush or rubber rolls. Masking material, such as protective lacquer or wax, may be coated in parallel lines using a slot die coater or an alternative standard coating process. This lacquer or wax can subsequently be removed using e.g. acetone or hot water.

### Example D

FIG. 14 shows an optical microscopy image of a cross-section of a sample where an elongated cavity has been formed in a lower layer 1403 and where an upper layer 1424 extends approximately 5 μm from the “bulk” and thus overhangs the cavity with approximately 5 micrometer.

Furthermore, a 500 nm silver layer 1464, 1466 was deposited on the sample which was positioned horizontally above the silver source, i.e. the normal of the sample surface was parallel to the line-of-sight direction from the silver source. The sample was mounted either using adhesive carbon pads or a small metal holder. The sample was coated with a silver layer using physical vapour deposition (E-beam evaporation, Alcatel machine). A 500 nm thick silver layer was produced at a deposition rate of ˜7 Å/s and a pressure of ˜6×10⁻⁶ mbar.

The figure shows that the silver layer is physically separated as indicated in the gap 1465 at the left side of the profile due to the undercut feature between the lower layer 1403, being a Hastelloy metal tape and the upper layer 1424, being an oxide/nitride surface coating. Importantly, about 5 μm of the undercut feature (which in the present figure is given by the overhanging remaining portion of the upper layer 1424) is sufficient to produce a significant separation of the silver layer 1464 on top of the upper layer 1424 and the silver layer 1466 at the bottom of the etched volume.

In the following, there is described embodiments of methods for producing a substrate suitable for supporting an elongated superconducting element. Note that the methods 1-4 described below specifies methods for making substrates, such as filament structures, with filling material and undercuts on only one side (which may be referred to as the upper side) of the substrate/metal tape/solid element and that the methods may in alternative embodiments encompassed by the present invention be applied on both sides simultaneously or sequentially, so as to enable producing substrates suitable for supporting an elongated superconducting element, where said substrates have one or more portions of filling material with corresponding undercut volumes on both an upper and a lower side.

### METHOD-1: “Masking Tape and Electroplating Using Two Different Ni-Types”

### METHOD-1A:

FIG. 16 illustrates the process flow for METHOD-1A, with sub-figures (a)-(h) corresponding to method steps 1-8 described below.

STEP 1 corresponding to FIG. 16(a): The raw substrate (which may be referred to as solid element) is cleaned using a standard degreaser [1].
STEP 2 corresponding to FIG. 16(b): A masking tape, such as adhesive Kapton tape, is applied to the bottom side of the substrate.
STEP 3 corresponding to FIG. 16(c): A standard Woods nickel strike [1] is electroplated on to the upper side of the substrate (this step is typically seen as advantageous for stainless steel and stainless alloy materials).
STEP 4 corresponding to FIG. 16(d): A standard bright nickel layer [1] is electroplated on to the Woods nickel strike layer (this standard bright nickel layer has a smoother surface which ensures a low surface roughness that is beneficial for further buffer layer growth and eventually the superconducting layer).
STEP 5 corresponding to FIG. 16(e): A masking material in the form of a masking tape, such as adhesive Kapton tape, is applied to the upper side of the substrate.
STEP 6 corresponding to FIG. 16(f): The masking tape is mechanically cut, e.g. with an angle, using knifes and the tape portions with an inverted trapeze (i.e., the portions which in the cross-section in FIG. 16(f) would have had an increasing with in a direction away from the solid element) is removed by peeling off the tape-parts. FIG. 16(f) illustrates the situation after said removal. Alternatively, the tape is cut before it is applied on to the bright nickel layer, and the portion which are shown in FIG. 16(f) are placed on the substrate. The remaining portions of tape correspond to elongated strips of masking material on the solid element.
STEP 7 corresponding to FIG. 16(g): An additional bright nickel layer is plated on to the areas not covered by the masking tape and this layer will fill up the portions adjacent to and between the masking material (remaining Kapton tape). This additional bright nickel layer corresponds to filling material.
STEP 8 corresponding to FIG. 16(h): The masking tape is peeled off (e.g. while applying heat to soften the masking tape), or dissolved using an appropriate solvent such as acetone, leaving only the metal structure on the surface, i.e, removing the one or more elongated strips of masking material so as to form one or more corresponding undercut volumes, where each undercut volume within the one or more undercut volumes is formed along a portion of filling material and between the portion of filling material and the solid element.

### METHOD-1B:

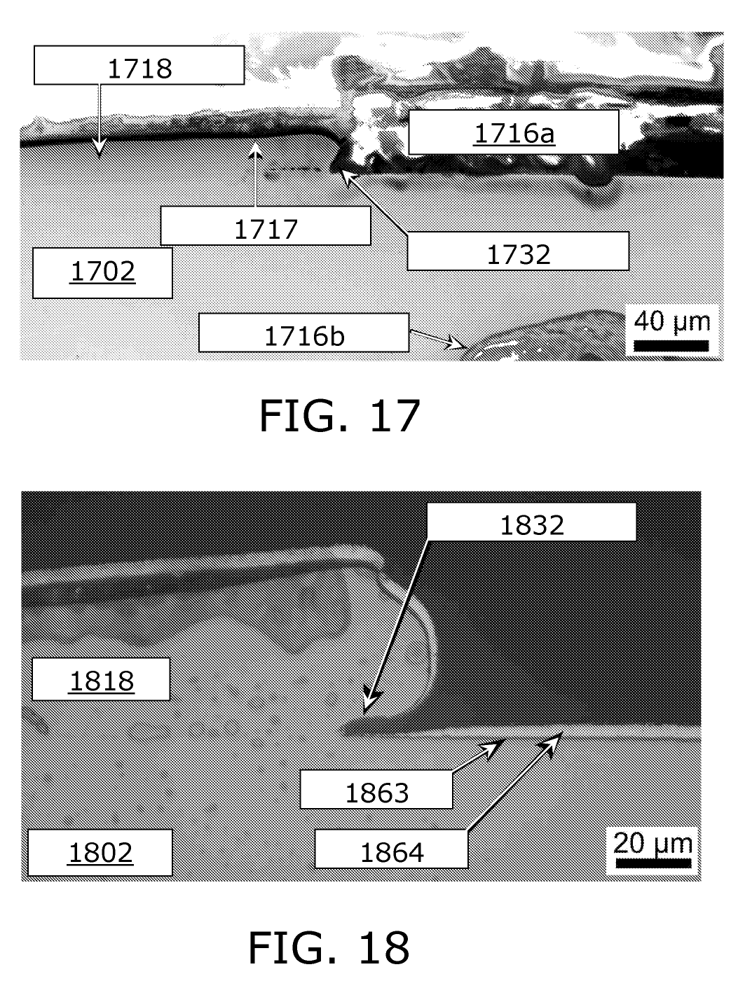

FIG. 17 shows a sample prepared following the processing steps described below.

The Hastelloy C276 metal tape 1702 (corresponding to a solid element) was degreased using an ultrasonic bath containing first acetone and then ethanol for 1 min each, respectively. The metal tape 1702 was then covered with masking tape (Kapton tape) on the lower side (see lower side masking tape 1716b in the bottom of FIG. 17) and on the upper side. The upper side Kapton tape was then cut using a 45° tilted knife in a reel-to-reel system and the Kapton tape strip with the inverted trapeze shape was peeled off leaving only the trapeze shaped portions 1716a (corresponding to the masking material as shown in FIG. 3C and FIG. 16(f)). The sample was emerged into a standard Woods nickel strike solution [1], which was heated to 32° C. The sample was then etched (anodic current) applying 16 mA/cm² for about 1 min with magnetic stirring (220 RPM). A nickel layer (Woods Ni layer 1718 corresponding to a homogeneous filling material) was then electroplated (cathodic current) onto the areas not covered by the masking tape 1716a-b using the standard Woods nickel solution that was still heated to 32° C. A pure nickel electrode (99.99%), 220 RPM magnetic stirring and a current density equal to 54 mA/cm² was applied for 12 min.

A thinner smooth bright nickel surface layer (bright Ni layer 1717) was electroplated, on top of the Woods nickel layer. A standard bright nickel solution, SurTec 856 [2] from SurTec Scandinavia ApS, was used and it was heated to 42° C., circulated using a pump system (flow in the range of 1-10 L/min) and electroplating was performed by applying 54 mA/cm² for about 1 min using a pure nickel electrode. The sample was following cleaned several times in deionized water, ethanol and finally dried using flowing N₂. Notice that in FIG. 17 the masking tape trapeze 1716a has not been removed.

The figure shows that an undercut volume 1732 is present between the homogeneous filling material 1718 and the solid element 1702.

### METHOD-1C:

FIG. 18 shows a sample with a metal tape 1802 and filling material 1818 prepared using the parameters described above in connection with the sample shown in FIG. 17, except that for the sample shown in FIG. 18 the masking tape has been completely removed and the substrate has subsequently to said removal been further coated with SiO₂ 1863 and subsequently Ag 1864 using a standard sputtering process. The figure shows, that the undercut volume 1832 causes a physical separation of the Ag layer on each side of the undercut volume.

### METHOD-2

### “Masking Tape and Electroplating Using Two Different Metals and Two Different Ni-Types”

### METHOD-2A:

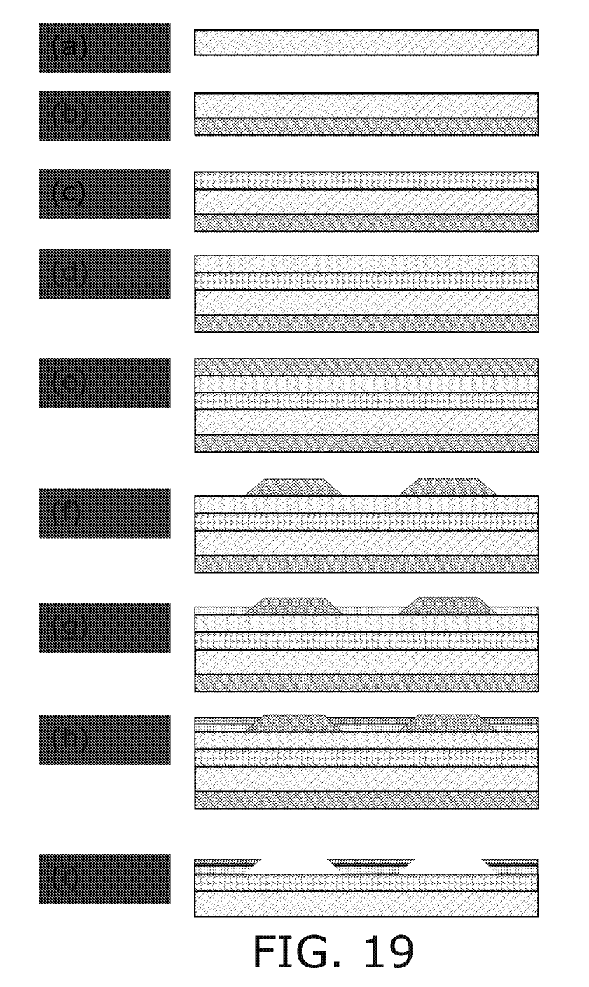

FIG. 19 illustrates the process flow for METHOD-2, with sub-figures (a)-(i) corresponding to method steps 1-9 described below.

STEP 1 corresponding to FIG. 19(a): The raw substrate (which may be referred to as solid element) is cleaned using a standard degreaser [1].
STEP 2 corresponding to FIG. 19(b): A masking tape such as adhesive Kapton tape is applied to the bottom side of the substrate.
STEP 3 corresponding to FIG. 19(c): A standard Woods nickel strike [1] is electroplated on to the upper side of the substrate (this step is typically seen as advantageous for stainless steel and stainless alloy materials).
STEP 4 corresponding to FIG. 19(d): A standard bright nickel layer [1] is electroplated plated on to the Woods nickel strike layer (this standard bright nickel layer has a smoother surface which ensures a low surface roughness that is beneficial for further buffer layer growth).
STEP 5 corresponding to FIG. 19(e): A masking tape, such as adhesive Kapton tape, is applied to the upper side of the substrate.
STEP 6 corresponding to FIG. 19(f): The masking tape is mechanically cut, e.g. with an angle, using knifes and the tape portions with an inverted trapeze (i.e., the portions which in the cross-section in FIG. 16(f) would have had an increasing with in a direction away from the solid element) is removed by peeling off the tape-parts. FIG. 16(f) illustrates the situation after said removal. Alternatively, the tape is cut before it is applied on to the bright nickel layer, and the portion which are shown in FIG. 16(f) are placed on the substrate. The remaining portions of tape correspond to elongated strips of masking material on the solid element.
STEP 7 corresponding to FIG. 19(g): A copper layer is electroplated onto the areas not covered by the masking tape using a standard sulfate-based Cu-plating solution [1].
STEP 8 corresponding to FIG. 19(h): A bright nickel layer is electroplated onto the areas not covered by the masking tape and it fills (“grows up against”) the portions not covered by the filling material (Kapton tape).
STEP 9 corresponding to FIG. 19(i): The masking tape is peeled off (e.g. while applying heat to soften the masking tape), or dissolved using an appropriate solvent such as acetone, leaving only the metal structure on the surface.

METHOD-2 differs from METHOD-1 in that the filling material is provided in a two-step process, which is reflected in STEP 6 and STEP 7 of METHOD-2A (and corresponding to FIGS. 19(g)-(h)). An advantage of such two-step process may be, that a core of a non-magnetic material (e.g., Cu) can be applied, and then a magnetic material may be applied thereto (e.g., Ni). An advantage of this may in turn enable benefiting from the good chemical properties of Ni (resistance towards oxidation) and the good magnetic properties of Cu (non-magnetic, which may enable reducing losses due to hysterisis).

### METHOD-2B:

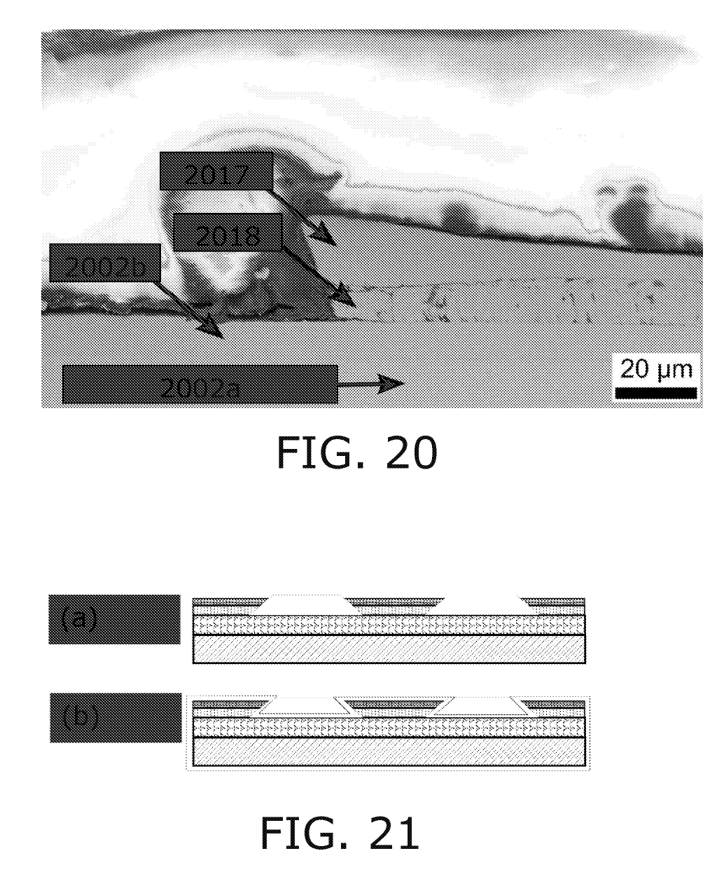

FIG. 20 shows a sample prepared following processing steps described below.

The Hastelloy C276 metal tape 2002a was degreased using an ultrasonic bath containing first acetone and then ethanol for 1 min each, respectively. The metal tape was then covered with masking Kapton tape on the lower side. The sample was then emerged into a standard Woods nickel strike solution [1], which was heated to 32° C. and then the sample was etched (anodic current) applying 16 mA/cm² for about 1 min with magnetic stirring (220 RPM). A nickel layer 2002b was then electroplated (cathodic current) onto the upper metal tape surface (which was at this point not covered by the masking tape) using the standard Woods nickel solution that was still heated to 32° C., a pure nickel electrode (99.99%), 220 RPM magnetic stirring and applying 54 mA/cm² for about 12 min. It is noted, that in this example, the tape 2002a and the nickel layer 200b may together be seen as a solid element.

The upper part of the metal tape 2002a with nickel layer 2002b was then covered with masking Kapton tape which was subsequently cut using a 45° tilted knife in a reel-to-reel system and the Kapton tape strip with the reversed trapeze shape was peeled off leaving only the trapeze shaped areas (corresponding to the masking material as shown in FIG. 3C and FIG. 19(f)).

A copper layer 2018 was electroplated onto the areas not covered by the masking tape using a standard sulfate-based copper bath solution [1] used at room temperature ˜25° C., electrodes were phosphorized (0.02-0.08% by weight phosphorus), oxide-free, high-purity copper nuggets on a Ti-rod placed in a standard anode bag, 220 RPM magnetic stirring and applying 30 mA/cm² for about 10 min.

A thinner smooth bright nickel surface layer 2017 was electroplated, on top of the copper layer 2018 using a standard bright nickel solution, SurTec 856 [2] from SurTec Scandinavia ApS, which was heated to 42° C., circulated using a pump system (flow in the range of 1-10 L/min) and electroplating was performed by applying 54 mA/cm² for about 1 min. The sample was following cleaned several times in deionized water, ethanol and finally dried using flowing N₂. The copper layer 2018 may be seen as a homogeneous filling material. Alternatively, The copper layer 2018 and bright nickel surface layer 2017 may be seen as filling material.

### METHOD-3

### “Filling Material Portions Made in Buffer Layer Using Chemical Solution Deposition”

STEP1: The raw substrate, such as Hastelloy C276 or Ni—W, is cleaned using a standard degreaser [1].
STEP2: A masking tape, such as adhesive Kapton tape is applied to the bottom side of the substrate.
STEP3: One or more buffer layer(s), such as Y₂O₃, Al₂O₃, Yttrium Stabilized Zirconium, CeO₂, MgO, Gd₂Zr₂O₇ is coated onto the upper side of the substrate using chemical solution deposition and coating by e.g. dip-coating or ink-jet printing, and may be alternatively be carried out before STEP2. The present step ensures a smooth surface and particularly if using the solution deposition planarization technique [3]. Additionally, if the metal substrate material is textured this may transfer the texture to the buffer layer (however, typically not for the solution deposition planarization). These layers are dried at an elevated temperature around e.g. 200° C., while final sintering at a higher temperature may be performed after the masking material has been removed. This buffer-covered substrate forms the solid element.
STEP4: A pre-cut (e.g. mechanically cut using 45° tilted knifes) adhesive Kapton tape is applied onto the dried buffer layers so as to form elongated strips of masking material, corresponding to the masking material in, e.g., FIG. 3C. This masking material may beneficially have a surface property that enables that subsequently deposited buffer layer material contact angle on the masking material is high (“hydrophobic”) so that it is not wetting the surface and therefore not covering/sticking to the masking material but enables subsequently deposited buffer layer material to be confined in the plane by the masking material portions.
STEP5: One or more additional buffer layer(s) are coated onto the tape, which additional buffer layers correspond to filling material, which then fills the portions between the masking materials and inherits the (inverse of the) shape of the masking material.
STEP6: The masking tape is peeled off (e.g. while applying heat to soften the masking tape), or dissolved using an appropriate solvent leaving only the buffer layer profile structure on the surface.
STEP7: The buffer layer material is sintered at an elevated temperature and further processed in view of coated conductor fabrication.

A possible advantage of METHOD-3 may be, that both the surfaces of the filling material and the surfaces of the solid element between the portions of filling material may be buffer material.

### METHOD-4

### “Masking Material Applied Using Ink-Jet Printing”

STEP1: The raw substrate, such as Hastelloy C276 or Ni-W, is cleaned using a standard degreaser [1].
STEP2: A masking tape, such as adhesive Kapton tape is applied to the bottom side of the substrate.
STEP3: A masking material is applied using ink-jet printing and produced so that narrow separated lines are formed, i.e., elongated strips of masking material is formed. The masking material may be appropriate for e.g. electroplating or chemical solution deposition of filling material. It is beneficial to utilize ink-jet printing or alternatively micro/nano-roll imprinting (imprint lithography) for this process, since the filament width can be reduced and filaments widths in the micro/nanometer range may be obtained.
STEP4: Either a series of electroplated layers (see e.g. METHOD-1A, STEPS 3-8) or a buffer layer filling (see METHOD-3, STEPS 5-7) is applied.

FIG. 21 illustrates an additional step. To any one of the last step in any one of the methods, in particular any one of METHODS-1-4, it may be beneficial to add an additional layer of e.g. Ni or Cr, which will cover the entire structure (as illustrated in FIGS. 21(a)-(b)), and have a layer thickness entailing that will not fill the undercut volume but will insure that e.g. electroplated copper is protected against oxygenation during further processing, such as a thickness of e.g. within 100 nm-1 μm.

REFERENCES for the preceding section describing methods 1-4, which references are each included by reference in entirety:
[1] Surface Finishing Guidebook, 79^{th} edition, 10th Issue by Metal Finishing Magazine, Fall 2011, VOLUME 109 NUMBER 11A,
[2] SURTEC 856, Glansnikkel for tromle og stel,
[3] Sheehan et al., Appl. Phys. Lett. 98, 071907 (2011); http://dx.doi.org/10.1063/1.3554754

To sum up, there is provided a method for producing a substrate (300) suitable for supporting an elongated superconducting element, wherein one or more elongated strips of masking material are placed on a solid element (202) so as to form one or more exposed elongated areas being delimited on one or two sides by elongated strip of masking material, and placing filling material on the solid element so that each exposed elongated area within the one or more exposed elongated areas is covered by a portion of filling material (318a-c) where each portion of filling material also covers at least a portion of the adjacent elongated strip of masking material and subsequently removing the one or more elongated strips of masking material so as to form one or more corresponding undercut volumes, where each undercut volume within the one or more undercut volumes is formed along a portion of filling material and between the portion of filling material and the solid element. The method may further comprise placing buffer material (640) and or superconducting material (642, 644, 646)) on the substrate, so as to provide a superconducting structure (601) with reduced AC losses.

In embodiments E1-E15 of the invention, there is presented:
E1.A method for producing a substrate (300) suitable for supporting an elongated superconducting element, the method comprising:
   Providing a solid element (202),
   Placing one or more elongated strips 316a-b of masking material on the solid element, where the one or more elongated strips of masking material are arranged so as to form one or more exposed elongated areas (323a-c), where each exposed elongated area within the one or more exposed elongated areas is delimited on one or two sides by at least one elongated strip of masking material within the one more elongated strips of masking material,
   Placing filling material (317) on the solid element so that each exposed elongated area within the one or more exposed elongated areas is covered by a portion of filling material (318a-c), where each portion of filling material also covers at least a portion of the adjacent elongated strip of masking material,
   Removing the one or more elongated strips of masking material so as to form one or more corresponding undercut volumes, where each undercut volume within the one or more undercut volumes is formed along a portion of filling material and between the portion of filling material and the solid element.
E2.A method for producing a substrate (300) suitable for supporting an elongated superconducting element according to any of the preceding embodiments, wherein the step of
   Placing one or more elongated strips of masking material on the solid element, where the one or more elongated strips of masking material are arranged so as to form one or more exposed elongated areas, where each exposed elongated area within the one or more exposed elongated areas is delimited on one or two sides by at least one elongated strip of masking material within the one more elongated strip of masking material,
comprises
   Placing a plurality of elongated strips of masking material on the solid element, where adjacent elongated strips of masking material within the plurality of elongated strips of masking material are arranged so as to form a plurality of exposed elongated areas, where each exposed elongated area within the one or more exposed elongated areas is formed adjacent to at least one elongated strip of masking material, and wherein one or more exposed elongated areas within the plurality of exposed elongated areas is formed between adjacent elongated strips of masking material.
E3.A method for producing a substrate (300) suitable for supporting an elongated superconducting element according to embodiment E2, where adjacent elongated strips of masking material within the plurality of elongated strips of masking material are substantially parallel with each other.
E4.A method for producing a substrate (300) suitable for supporting an elongated superconducting element according to any of the preceding embodiments, wherein the solid element is an ellipsoidal cylinder.
E5.A method for producing a substrate (300) suitable for supporting an elongated superconducting element according to any one of embodiments E2-E3, wherein a distance (752) between adjacent elongated strips of masking material within the plurality of elongated strips of masking material is within 1 micrometer-1 millimeter.
E6.A method for producing a substrate (300) suitable for supporting an elongated superconducting element according to any of the preceding embodiments, wherein a distance (748) is given between a plane being tangential to upper surfaces of the one or more portions of filling material (318a-c) after the step of
   Removing the one or more elongated strips of masking material so as to form one or more corresponding undercut volumes, where each undercut volume within the one or more undercut volumes is formed along a portion of filling material and between the portion of filling material and the solid element,
and a plane being tangential to bottoms of volumes bounded on at least two sides by the solid element and one or more adjacent portions of filling material, and wherein said distance (748) is large enough so as to enable that a superconducting material placed on the substrate may have portions
   on the bottoms of volumes bounded on at least two sides by the solid element and one or more adjacent portions of filling material,
and/or
   on the one or more portions of filling material,
which portions of superconducting material are physically separated.
E7.A method for producing a substrate (300) suitable for supporting an elongated superconducting element according to any of the preceding embodiments, wherein the method further comprises placing a layer of buffer material (640) on
   the one or more portions of filling material (318a-c)
and/or on
   one or more sides of the volumes bounded on at least two sides by the solid element and one or more adjacent portions of filling material.
E8.A method for producing an elongated superconducting element (601), wherein the method comprises the steps of producing a substrate suitable for supporting an elongated superconducting element according to any one of embodiments E1-E7, and wherein the method further comprises placing a layer of superconducting material (642, 644, 646)
   on the one or more portions of filling material (318a-c)
and/or on
   a bottom of volumes bounded on at least two sides by the solid element and one or more adjacent portions of filling material,
so that the undercut volumes (332) serve to physically separate individual lines of superconducting material.
E9.A method for producing an elongated superconducting element (601), wherein the method comprises the steps of producing a substrate suitable for supporting an elongated superconducting element according to any one of embodiments E1-E7, and wherein the method further comprises placing,
   c. a layer of buffer material (640)
      on the one or more portions of filling material (318a-c)
      and/or
      on bottoms of volumes bounded on at least two sides by the solid element and one or more adjacent portions of filling material,
      of the substrate suitable for supporting an elongated superconducting element provided according to any one of embodiments E1-E7, and
   d. a layer of superconducting material (642, 644, 646) on the buffer material,
so that the undercut volumes (332) serve to physically separate individual lines of superconducting material and/or buffer material.
E10. A method for producing an elongated superconducting element (601) according to any one of embodiments E8-E9, wherein the step of placing a layer of superconducting material (642, 644, 646) and/or a layer of buffer material (640) is a line-of-sight process.
E11. A substrate (300) suitable for supporting an elongated superconducting element, the substrate comprising:
   A solid element,
   One or more portions of filling material on the solid element and arranged so that a plurality of undercut volumes is formed along each portion of filling material and between the portion of filling material and the solid element.
E12. A substrate (300) suitable for supporting an elongated superconducting element according to embodiment E11, wherein the substrate is a tape.
E13. An elongated superconducting element (601) comprising:
   A substrate according to any one of embodiments E11-E12,
   a superconducting layer placed on the substrate or on a buffer on the substrate, so that the undercut volumes (332) physically separates individual lines of superconducting material or so that the undercut volumes (332) serve to physically separate individual lines of superconducting material and/or buffer material.
E14. An apparatus for carrying out the method according to any one of embodiments E1-E10.
E15. Use of an elongated superconducting element (601) according to embodiment E13, within any one of a performance magnetic coil, a transformer, a generator, a motor, an electro-motor, a magnetic resonance scanner, a cryostat magnet, a large hadron collider, an AC power grid cable, a smart grid.

For the above embodiments E1-E15, it may be understood that reference to preceding ‘embodiments’ may refer to preceding embodiments within embodiments E1-E15.

Although the present invention has been described in connection with the specified embodiments, it should not be construed as being in any way limited to the presented examples. The scope of the present invention is set out by the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

1. A method for producing a substrate suitable for supporting an elongated superconducting element, the method comprising:
providing a solid element,
placing one or more elongated strips of masking material on the solid element, where the one or more elongated strips of masking material are arranged so as to form one or more exposed elongated areas, where each exposed elongated area within the one or more exposed elongated areas is delimited on one or two sides by at least one elongated strip of masking material within the one more elongated strips of masking material,
placing filling material on the solid element so that each exposed elongated area within the one or more exposed elongated areas is covered by a portion of filling material, where each portion of filling material also covers at least a portion of the adjacent elongated strip of masking material, and
removing the one or more elongated strips of masking material so as to form one or more corresponding undercut volumes, where each undercut volume within the one or more undercut volumes is formed along a portion of filling material and between the portion of filling material and the solid element.

2-20. (canceled)

21. The method for producing a substrate suitable for supporting an elongated superconducting element according to claim 1, wherein the step of:
placing one or more elongated strips of masking material on the solid element, where the one or more elongated strips of masking material are arranged so as to form one or more exposed elongated areas, where each exposed elongated area within the one or more exposed elongated areas is delimited on one or two sides by at least one elongated strip of masking material within the one more elongated strip of masking material, comprises:
placing a plurality of elongated strips of masking material on the solid element, where adjacent elongated strips of masking material within the plurality of elongated strips of masking material are arranged so as to form a plurality of exposed elongated areas, where each exposed elongated area within the one or more exposed elongated areas is formed adjacent to at least one elongated strip of masking material, and wherein one or more exposed elongated areas within the plurality of exposed elongated areas is formed between adjacent elongated strips of masking material.

22. The method for producing a substrate suitable for supporting an elongated superconducting element according to claim 21, where adjacent elongated strips of masking material within the plurality of elongated strips of masking material are substantially parallel with each other.

23. The method for producing a substrate suitable for supporting an elongated superconducting element according to claim 1, wherein the solid element is an ellipsoidal cylinder.

24. The method for producing a substrate suitable for supporting an elongated superconducting element according to claim 21, wherein a distance between adjacent elongated strips of masking material within the plurality of elongated strips of masking material is within 1 micrometer-10 millimeter.

25. The method for producing a substrate suitable for supporting an elongated superconducting element according to claim 1, wherein a distance is given between a plane being tangential to upper surfaces of the one or more portions of filling material after the step of:
removing the one or more elongated strips of masking material so as to form one or more corresponding undercut volumes, where each undercut volume within the one or more undercut volumes is formed along a portion of filling material and between the portion of filling material and the solid element,
and a plane being tangential to bottoms of volumes bounded on at least two sides by the solid element and one or more adjacent portions of filling material, and wherein said distance is large enough so as to enable that a superconducting material placed on the substrate may have portions
on the bottoms of volumes bounded on at least two sides by the solid element and one or more adjacent portions of filling material,
and/or
on the one or more portions of filling material,
which portions of superconducting material are physically separated.

26. The method for producing a substrate suitable for supporting an elongated superconducting element according to claim 1, wherein the method further comprises placing a layer of buffer material on
the one or more portions of filling material
and/or on
one or more sides of the volumes bounded on at least two sides by the solid element and one or more adjacent portions of filling material.

27. A method for producing an elongated superconducting element, wherein the method comprises:
producing a substrate suitable for supporting an elongated superconducting element according to claim 1, and wherein the method further comprises placing a layer of superconducting material
on the one or more portions of filling material
and/or on
a bottom of volumes bounded on at least two sides by the solid element and one or more adjacent portions of filling material,
so that the undercut volumes serve to physically separate individual lines of superconducting material.

28. The method for producing an elongated superconducting element, wherein the method comprises:
producing a substrate suitable for supporting an elongated superconducting element according to claim 1, and wherein the method further comprises placing,
a layer of buffer material
on the one or more portions of filling material
and/or
on bottoms of volumes bounded on at least two sides by the solid element and one or more adjacent portions of filling material,
of the substrate suitable for supporting an elongated superconducting element, and
a layer of superconducting material on the buffer material,
so that the undercut volumes serve to physically separate individual lines of superconducting material and/or buffer material.

29. The method for producing an elongated superconducting element according to claim 27, wherein the step of placing a layer of superconducting material and/or a layer of buffer material is a line-of-sight process.

30. A substrate suitable for supporting an elongated superconducting element, the substrate comprising:
a solid element, and
a plurality of portions of filling material on the solid element and arranged so that a plurality of undercut volumes is formed along each portion of filling material and between the portion of filling material and the solid element, wherein a length of the substrate is at least 1 m.

31. The substrate suitable for supporting an elongated superconducting element according to claim 30, wherein the substrate is a tape.

32. The substrate suitable for supporting an elongated superconducting element according to claim 30, wherein the filling material is a homogeneous material.

33. The substrate suitable for supporting an elongated superconducting element according to claim 30, comprising a plurality of portions of filling material being substantially parallel and wherein one or more portions of a surface of the solid element upon which the filling material is placed, said one or more portions of said surface being placed between said portions of filling material, is/are substantially planar.

34. The substrate suitable for supporting an elongated superconducting element according to claim 30 comprising a plurality of portions of filling material that is substantially parallel, wherein a surface of the solid element upon which the filling material is placed, is substantially planar.

35. The substrate suitable for supporting an elongated superconducting element according to claim 30, wherein the substrate is a tape, wherein the length of the substrate is at least 1 m, wherein the filling material is a homogeneous material, wherein said substrate comprises a plurality of portions of filling material that are substantially parallel, and wherein one or more portions of a surface of the solid element, upon which the filling material is placed, said one or more portions of said surface is placed between said portions of filling material, is/are substantially planar.

36. An elongated superconducting element comprising:
A substrate according to claim 30, and
a superconducting layer placed on the substrate or on a buffer on the substrate, so that the undercut volumes physically separates individual lines of superconducting material or so that the undercut volumes serve to physically separate individual lines of superconducting material and/or buffer material.

37. The elongated superconducting element according to claim 36 incorporated within a performance magnetic coil, a transformer, a generator, a motor, an electro-motor, a magnetic resonance scanner, a cryostat magnet, a large hadron collider, an AC power grid cable, a DC power grid cable, or a smart grid a tokamak .
